(19) United States
(12) Patent Application Publication
(10) Pub. No.: US 2026/0068465 A1
(43) Pub. Date: Mar. 5, 2026

(54) DISPLAY PANEL AND ELECTRONIC DEVICE INCLUDING THE SAME

(71) Applicant: Samsung Display Co., Ltd., Yongin-si (KR)

(72) Inventors: Donglim Kim, Yongin-si (KR); Donghyun Son, Yongin-si (KR); Ilgoo Youn, Yongin-si (KR); Bongwon Lee, Yongin-si (KR); Wonsang Park, Yongin-si (KR); Youngtaeg Jung, Yongin-si (KR); Mincheol Chae, Yongin-si (KR)

(21) Appl. No.: 19/311,828

(22) Filed: Aug. 27, 2025

(30) Foreign Application Priority Data
Aug. 30, 2024 (KR) 10-2024-0117883

(51) Int. Cl. H10K 59/131; H10K 59/121

(52) U.S. Cl. CPC H10K 59/131; H10K 59/1213

(57) ABSTRACT

A display panel and an electronic device includes first display elements in a first display region, first sub-pixel circuits in a third display region and electrically connected to the first display elements, respectively, and connection wires electrically connecting the first display elements to the first sub-pixel circuits, respectively, wherein the first display elements include first-1 display elements in an a^{th} row and first-2 display elements in a b^{th} row, the first sub-pixel circuits include first-1 sub-pixel circuits in the a^{th} row and electrically connected to the first-1 display elements, the connection wires include first connection wires connecting the first-1 display elements to the first-1 sub-pixel circuits, the number of the first-1 display elements in the a^{th} row is greater than the number of the first-2 display elements in the b^{th} row, and one of the first connection wires includes a portion extending along the b^{th} row.

### CROSS-REFERENCE TO RELATED APPLICATION

The present application claims priority to Korean Patent Application No. 10-2024-0117883, filed on Aug. 30, 2024, in the Korean Intellectual Property Office, the entire disclosure of which is incorporated herein by reference.

### BACKGROUND

### 1. Field

Aspects of some embodiments of the present disclosure relate to a display panel and an electronic device including the same.

### 2. Description of the Related Art

Display panels are apparatuses that visually display data. Display panels are being applied in increasingly diverse ways. In addition, display panels are being manufactured to be thinner and lighter, thereby allowing for a wider range of uses.

Such display panels are divided into a display region and a peripheral region outside the display region. A plurality of sub-pixels are arranged in the display region, and each of the sub-pixels includes an organic light-emitting diode and a sub-pixel circuit electrically connected to the organic light-emitting diode. The peripheral region may include various wires for transferring electrical signals to the display region, a scan driver, a data driver, a controller, etc.

The above information disclosed in this Background section is only for enhancement of understanding of the background and therefore the information discussed in this Background section does not necessarily constitute prior art.

### SUMMARY

Aspects of some embodiments of the present disclosure include a display panel with relatively improved reliability and relatively improved visibility and an electronic device including the same. However, the disclosed embodiments are only examples, and the scope of embodiments according to the present disclosure is not limited thereto.

Additional aspects will be set forth in part in the description which follows and, in part, will be apparent from the description, or may be learned by practice of the presented embodiments of the disclosure.

According to one or more embodiments of the present disclosure, a display panel includes a substrate including a first display region, a second display region surrounding at least a portion of the first display region, and a third display region arranged between the first display region and the second display region, a plurality of first display elements arranged along a plurality of rows and a plurality of columns, in the first display region, a plurality of first sub-pixel circuits arranged in the third display region and electrically connected to the plurality of first display elements, respectively, and a plurality of connection wires electrically connecting the first display elements to the first sub-pixel circuits, respectively, wherein the plurality of first display elements include first-1 display elements arranged in an a^{th} row and first-2 display elements arranged in a b^{th} row (wherein a and b are different natural numbers), the plurality of first sub-pixel circuits include first-1 sub-pixel circuits arranged in the a^{th} row and electrically connected to the first-1 display elements, respectively, the plurality of connection wires include first connection wires connecting the first-1 display elements to the first-1 sub-pixel circuits, respectively, a number of the first-1 display elements arranged in the a^{th} row is greater than a number of the first-2 display elements arranged in the b^{th} row, and one of the first connection wires includes a portion extending along the b^{th} row.

According to some embodiments, a width of the first display region in a row direction in the a^{th} row may be greater than a width of the first display region in the row direction in the b^{th} row.

According to some embodiments, at least a portion of each of the plurality of connection wires may include a metal or an alloy.

According to some embodiments, at least a portion of each of the plurality of connection wires may include at least one of aluminum, copper, molybdenum, titanium, or alloys thereof.

According to some embodiments, a portion of each of the plurality of connection wires may include a transparent conductive material, and the remaining portion of each of the plurality of connection wires may include a metal or an alloy.

According to some embodiments, each of the plurality of connection wires may include a first portion arranged in the first display region and including a transparent conductive material and a second portion arranged in the third display region and including a metal or an alloy.

According to some embodiments, the first portion and the second portion of each of the plurality of connection wires may be arranged on different layers from each other.

According to some embodiments, one of the plurality of connection wires may include a metal or an alloy, and at least a portion of another one of the plurality of connection wires may include a transparent conductive material.

According to some embodiments, the other one of the plurality of connection wires may include a third portion arranged in the first display region and including a transparent conductive material and a fourth portion arranged in the third display region and including a metal or an alloy.

According to some embodiments, another one of the first connection wires may extend along the a^{th} row.

According to some embodiments, the plurality of first display elements may further include first-3 display elements arranged in a c^{th} row (wherein c is a natural number different from a and b), the plurality of first sub-pixel circuits may further include first-2 sub-pixel circuits arranged in the b^{th} row and electrically connected to the first-2 display elements, respectively, and first-3 sub-pixel circuits arranged in the c^{th} row and electrically connected to the first-3 display elements, respectively, the plurality of connection wires may further include second connection wires connecting the first-2 display elements to the first-2 sub-pixel circuits, respectively, a number of the first-2 display elements arranged in the b^{th} row may be greater than a number of the first-3 display elements arranged in the c^{th} row, and one of the second connection wires may include a portion extending along the c^{th} row.

According to some embodiments, another one of the second connection wires may extend along the b^{th} row.

According to some embodiments, the display panel may further include a plurality of second display elements arranged in the second display region, a plurality of second sub-pixel circuits arranged in the second display region and electrically connected to the plurality of second display elements, respectively, a plurality of third display elements arranged in the third display region, and a plurality of third sub-pixel circuits arranged in the third display region and electrically connected to the plurality of third display elements, respectively.

According to one or more embodiments of the present disclosure, a display panel includes a first display region, a second display region surrounding at least a portion of the first display region and having lower transmittance than the first display region, and a third display region arranged between the first display region and the second display region, a plurality of display elements arranged in the first display region, a plurality of sub-pixel circuits arranged in the third display region and electrically connected to the plurality of display elements, respectively, and a plurality of connection wires electrically connecting the display elements to the sub-pixel circuits, respectively, wherein one connection wire among the connection wires includes a first portion arranged in the first display region and including a transparent conductive material and a second portion arranged in the third display region and including a metal or an alloy.

According to some embodiments, the plurality of display elements may include a plurality of first display elements arranged in an a^{th} row of the first display region and a plurality of second display elements arranged in a b^{th} row of the first display region (wherein a and b are different natural numbers), a width of the first display region in a row direction in the a^{th} row may be greater than a width of the first display region in the row direction in the b^{th} row, the first display elements may include a first-1 display element and a first-2 display element, among the plurality of connection wires, a first connection wire connected to the first-1 display element may include a portion extending along the b^{th} row, and among the plurality of connection wires, a second connection wire connected to the first-2 display element may extend along the a^{th} row.

According to some embodiments, the first-1 display element may be arranged in an r^{th} column, the first-2 display element may be arranged in a q^{th} column (wherein r and q are different natural numbers), and a width of the first display region in a column direction in the r^{th} column may be greater than a width of the first display region in the column direction in the q^{th} column.

According to some embodiments, the first-1 display element may be arranged closer to a center of the first display region than the first-2 display element may be.

According to some embodiments, each of the connection wires may include the first portion and the second portion.

According to some embodiments, another one of the connection wires may include a third portion arranged in the first display region and a fourth portion arranged in the third display region, wherein each of the third and fourth portions may include a metal or an alloy.

According to one or more embodiments of the present disclosure, an electronic device includes a display panel including a first display region, a second display region surrounding at least a portion of the first display region, and a third display region arranged between the first display region and the second display region, and a component arranged on a lower surface of the display panel and overlapping at least a portion of the first display region, wherein the display panel includes a plurality of first display elements arranged along a plurality of rows and a plurality of columns, in the first display region, a plurality of first sub-pixel circuits arranged in the third display region and electrically connected to the plurality of first display elements, respectively, and a plurality of connection wires electrically connecting the first display elements to the first sub-pixel circuits, respectively, the plurality of first display elements include first-1 display elements arranged in an a^{th} row and first-2 display elements arranged in a b^{th} row (wherein a and b are different natural numbers), the plurality of first sub-pixel circuits include first-1 sub-pixel circuits arranged in the a^{th} row and electrically connected to the first-1 display elements, respectively, the plurality of connection wires include first connection wires connecting the first-1 display elements to the first-1 sub-pixel circuits, respectively, a number of the first-1 display elements arranged in the a^{th} row is greater than a number of the first-2 display elements arranged in the b^{th} row, and one of the first connection wires includes a portion extending along the b^{th} row.

### BRIEF DESCRIPTION OF THE DRAWINGS

The above and other aspects, features, and characteristics of certain embodiments of the disclosure will be more apparent from the following description taken in conjunction with the accompanying drawings, in which:

FIGS. 1A and 1B are each a perspective view schematically showing an electronic device according to some embodiments;

FIGS. 2A and 2B are each a cross-sectional view schematically showing an electronic device according to some embodiments;

FIGS. 3A and 3B are each a plan view schematically showing a display panel according to some embodiments;

FIG. 4 is an equivalent circuit diagram schematically showing a sub-pixel circuit electrically connected to a light-emitting diode corresponding to one sub-pixel arranged on a display panel according to some embodiments;

FIG. 5 is a cross-sectional view showing a structure of the display panel in a second display region, according to some embodiments, and is a cross-sectional view of the display panel of FIG. 3A taken along a line A-A′ shown in FIG. 3A;

FIG. 6 is a cross-sectional view showing a structure of a display panel in a first display region and a third display region, according to some embodiments, and is a cross-sectional view showing the display panel of FIG. 3A taken along a line B-B′ shown in FIG. 3A;

FIG. 7 is a plan view schematically showing a first display region and a third display region of a display panel according to some embodiments;

FIG. 8 is a plan view showing a portion of each of a first display region and a third display region of a display panel according to some embodiments, and is an enlarged view schematically showing an enlarged region ‘E’ of FIG. 7;

FIG. 9 is a plan view showing the density of connection wires in a first display region of a display panel according to some embodiments;

FIG. 10 is a plan view showing the density of connection wires in a first display region of a display panel according to a comparative example;

FIG. 11 is a plan view showing a portion of each of a first display region and a third display region of a display panel according to some embodiments, and is an enlarged view schematically showing an enlarged region ‘E’ of FIG. 7;

FIG. 12 is a plan view showing a portion of each of a first display region and a third display region of a display panel according to some embodiments, and is an enlarged view schematically showing an enlarged region ‘E’ of FIG. 7;

FIG. 13 is a block diagram of an electronic device according to an embodiment; and

FIG. 14 is a schematic diagrams of electronic devices according to various embodiments.

### DETAILED DESCRIPTION

Reference will now be made in more detail to aspects of some embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the disclosure, and a method to achieve the same, will be clearer referring to the detailed descriptions below with the drawings. However, the present embodiments may be implemented in various forms, not by being limited to the embodiments presented below.

Hereinafter, embodiments of the present disclosure will be described in detail with reference to the accompanying drawings, and in the description with reference to the drawings, the same or corresponding components are indicated by the same reference numerals and some redundant descriptions thereof may be omitted.

In the following embodiments, it will be understood that although the terms “first,” “second,” etc. may be used herein to describe various components, these components should not be limited by these terms. These terms are only used to distinguish one component from another.

In the following embodiments, the expression of singularity in the present specification includes the expression of plurality unless clearly specified otherwise in context.

In the following embodiments, it will be further understood that the terms “comprises” and/or “comprising” used herein specify the presence of stated features or components, but do not preclude the presence or addition of one or more other features or components.

In the following embodiments, it will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, because sizes and thicknesses of components in the drawings are arbitrarily illustrated for convenience of explanation, the following embodiments are not limited thereto.

In the present specification, the expression “A and/or B” represents A, B, or A and B. In addition, the expression “at least one of A and B” represents A, B, or A and B.

It will be understood that when a layer, region, or component is referred to as being “connected to” another layer, area, or component, it can be directly or indirectly connected to the other layer, region, or component. That is, for example, intervening layers, regions, or components may be present. For example, in the present specification, when a layer, region, or component is electrically connected to another layer, region, or component, the layers, regions, or components may not only be directly electrically connected, but may also be indirectly electrically connected via another layer, region, or component therebetween.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

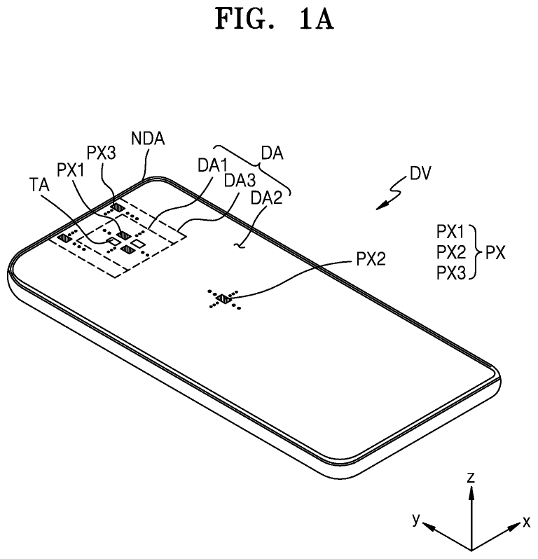

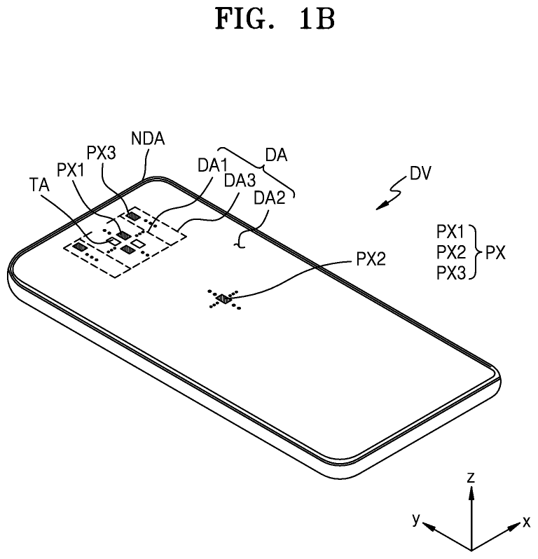

FIGS. 1A and 1B are each a perspective view schematically showing an electronic device DV according to some embodiments.

Referring to FIGS. 1A and 1B, the electronic device DV may include a display region DA and a non-display region NDA outside (e.g., surrounding, in a periphery, or outside a footprint of) the display region DA. The display region DA may include a first display region DA1, a second display region DA2, and a third display region DA3. A sub-pixel PX may be arranged in the first display region DA1, the second display region DA2, and the third display region DA3, and the sub-pixel PX may not be arranged in the non-display region NDA. The electronic device DV may display images to the outside by using light emitted from the sub-pixel PX arranged in the display region DA.

The sub-pixel PX may be defined as a region in which a display element emits light. The electronic device DV may include a plurality of sub-pixels PX. Each of the plurality of sub-pixels PX may emit light, and for example, may be a red sub-pixel, a green sub-pixel, or a blue sub-pixel. According to some embodiments, the electronic device DV may include a first sub-pixel PX1, a second sub-pixel PX2, and a third sub-pixel PX3.

The second display region DA2 may at least partially surround the first display region DA1 and the third display region DA3. According to some embodiments, the second display region DA2 may only partially surround the first display region DA1 and the third display region DA3. According to some embodiments, the second display region DA2 may entirely surround the first display region DA1 and the third display region DA3. The second display region DA2 may include the second sub-pixel PX2. The second sub-pixel PX2 may be provided as a plurality in the second display region DA2.

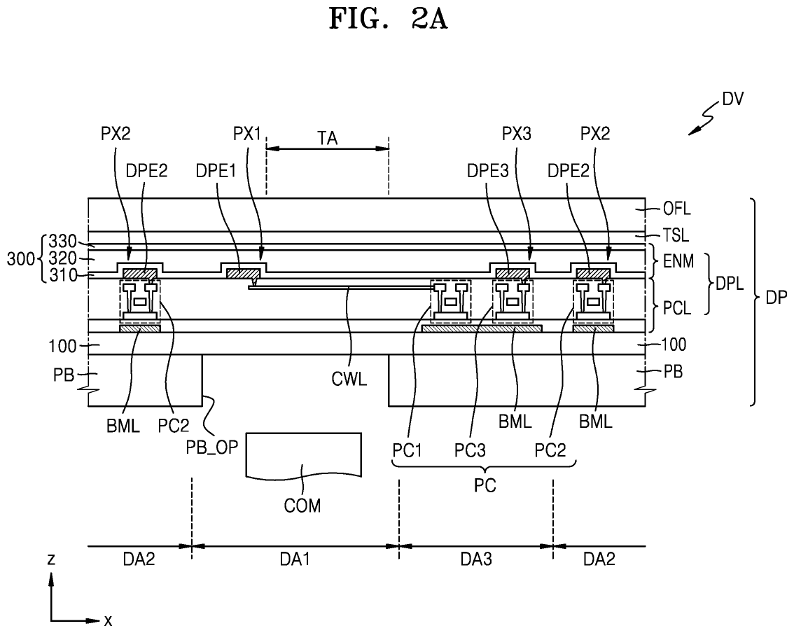

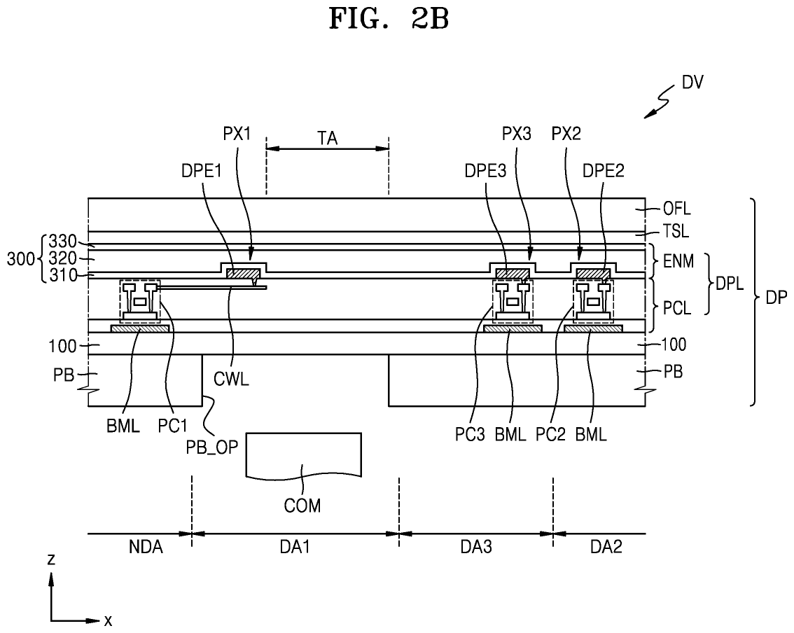

At least one of the first display region DA1 or the third display region DA3 may be a region overlapping a component. For example, as described below with reference to FIG. 2A, in the first display region DA1, a component COM (FIG. 2A), which is an electronic component, may be arranged on a lower portion of the electronic device DV in correspondence to the first display region DA1. At least one of the first display region DA1 or the third display region DA3 may include a transmission region TA (FIG. 2A) through which light or/and sound output from the component COM to the outside or traveling toward the component COM from the outside may be transmitted.

At least one of the first display region DA1 or the third display region DA3 may be a region overlapping the component COM (FIG. 2A) and having the sub-pixel PX arranged therein. According to some embodiments, the first display region DA1 may be a region overlapping the component COM and having the sub-pixel PX arranged therein. According to some embodiments, the first display region DA1 and the third display region DA3 may each be a region overlapping the component COM and having the sub-pixel PX arranged therein. According to some embodiments, the first sub-pixel PX1 may be arranged in the first display region DA1. The first sub-pixel PX1 may be provided as a plurality in the first display region DA1. The third sub-pixel PX3 may be arranged in the third display region DA3. The third sub-pixel PX3 may be provided as a plurality in the third display region DA3.

According to some embodiments, an image displayed in at least one of the first display region DA1 or the third display region DA3 may have a lower resolution than an image displayed in the second display region DA2. For example, the resolution of the first display region DA1 may be ½, ⅜, ⅓, ¼, 2/9, ⅛, 1/9, 1/16, etc. (or about ½, ⅜, ⅓, ¼, 2/9, ⅛, 1/9, 1/16, etc.) of the resolution of the second display region DA2. For example, the resolution of the second display region DA2 may be at least 400 ppi (or about 400 ppi), and the resolution of the first display region DA1 may be 200 ppi (or about 200 ppi) or 100 ppi (or about 100 ppi). According to some embodiments, the resolution of at least one of the first display region DA1 or the third display region DA3 may be equal to the resolution of the second display region DA2.

At least one of the first display region DA1 or the third display region DA3 may overlap the component COM and include the transmission region TA (FIG. 2A). The number of sub-pixels PX that may be arranged per unit area in at least one of the first display region DA1 or the third display region DA3 may be less than the number of sub-pixels PX arranged per unit area in the second display region DA2. For example, the number of first sub-pixels PX1 that may be arranged per unit area in the first display region DA1 may be less than the number of second sub-pixels PX2 arranged per unit area in the second display region DA2.

At least one of the first display region DA1 or the third display region DA3 may have high transmittance with respect to light or sound. For example, the transmittance of the electronic device DV in at least one of the first display region DA1 or the third display region DA3 may be at least 10% (or about 10%), for example, at least 40%, at least 25%, at least 50%, at least 85%, or at least 90%.

The electronic device DV may include at least one first display region DA1. For example, the electronic device DV may include one first display region DA1 or may include a plurality of first display regions DA1.

The third display region DA3 may be adjacent to the first display region DA1. According to some embodiments, the third display region DA3 may be arranged on one side of the first display region DA1. For example, the first display region DA1 and the third display region DA3 may be arranged side by side in a first direction (for example, x direction or −x direction). For example, the first display region DA1 and the third display region DA3 may be arranged side by side in a second direction (for example, y direction or −y direction). According to some embodiments, the third display region DA3 may be arranged at opposite sides of the first display region DA1. According to some embodiments, the third display region DA3 may be arranged between the first display region DA1 and the second display region DA2. According to some embodiments, the third display region DA3 may surround at least a portion of the first display region DA1.

FIGS. 1A and 1B show that the first display region DA1 and the third display region DA3 are arranged at the center of the upper side of the electronic device DV, but the disclosure is not limited thereto. For example, the first display region DA1 and the third display region DA3 may be arranged on the lower side, right side, or left side of the electronic device DV.

According to some embodiments, at least one of the first display region DA1 or the third display region DA3 may have various shapes such as a circle or an oval, or a polygonal shape such as a quadrangle, a star shape, a diamond shape, or an irregular shape.

The non-display region NDA may surround at least a portion of the display region DA. According to some embodiments, the non-display region NDA may surround at least a portion of the second display region DA2. According to some embodiments, the non-display region NDA may entirely surround the second display region DA2. According to some embodiments, the non-display region NDA may entirely surround the first display region DA1, the second display region DA2, and the third display region DA3.

FIGS. 1A and 1B show examples in which the electronic device DV is a smartphone, but embodiments according to the present disclosure are not limited thereto. For example, the electronic device DV according to some embodiments may be a portable electronic device, such as a mobile phone, a smartphone, a tablet personal computer (PC), a mobile communication terminal, an electronic organizer, an e-book, a portable multimedia player (PMP), a navigation device, or an ultra mobile PC (UMPC). The electronic device DV according to some embodiments may be a wearable electronic device, such as a smart watch, a watch phone, a glasses-type display, and a head-mounted display (HMD). The electronic device DV according to some embodiments may be used as an instrument panel of vehicles, a center information display (CID) arranged on the center fascia or dashboard of vehicles, a room mirror display in place of side-view mirrors of vehicles, or a display screen arranged at the rear side of a front seat as an entertainment for a rear seat of vehicles.

FIGS. 2A and 2B are each a cross-sectional view schematically showing a portion of the electronic device DV according to some embodiments.

Referring to FIGS. 2A and 2B, the electronic device DV may include a display panel DP and the component COM arranged to overlap the display panel DP. In addition, the electronic device DV may further include a housing that accommodates or encloses the display panel DP and the component COM of the electronic device DV and a cover window that is arranged on an upper portion or upper surface of the electronic device DV to protect the display panel DP from damage due to impacts from external objects or falling, or from external contaminants.

The display panel DP may include a substrate 100, a display layer DPL on the substrate 100, a touch screen layer TSL, an optical functional layer OFL, and a panel protection member PB arranged under the substrate 100. The electronic device DV may include the display panel DP.

The component COM may be an electronic element that uses light or sound. For example, the electronic element may be a sensor that measures distance such as a proximity sensor, a sensor that recognizes parts (for example, fingerprint, iris, face, etc.) of a user's body, a small lamp that output light, or an image sensor (for example, a camera) that captures an image. The electronic element that uses light may use light in various wavelength bands, such as visible light, infrared light, and ultraviolet light. The electronic element that uses sound may use ultrasonic waves or sounds of other frequency bands. According to some embodiments, the component COM may include sub-components such as a light-emitting unit and a light-receiving unit. The light-emitting unit and the light-receiving unit may be integrated with each other, or may be physically separate, and the pair of the light-emitting unit and the light-receiving unit may form one component COM.

The display panel DP may include the first display region DA1, the second display region DA2, and the third display region DA3. In other words, the first display region DA1, the second display region DA2, and the third display region DA3 may be defined in the substrate 100 and a multilayer film on the substrate 100. Hereinafter, detailed description is provided based on the assumption that the substrate 100 includes the first display region DA1, the second display region DA2, and the third display region DA3.

The display layer DPL may include a pixel circuit layer PCL including a sub-pixel circuit PC, a display element layer including a display element which is a light-emitting device, and a sealing member ENM such as an encapsulation layer 300 or a sealing substrate. An insulating layer may be arranged between the substrate 100 and the display layer DPL and within the display layer DPL. The display element may include a light-emitting diode, and according to some embodiments, the display element may be an organic light-emitting diode. Hereinafter, it is described that a light-emitting diode includes an organic light-emitting diode, but embodiments according to the present disclosure are not limited thereto. According to some embodiments, the display element of the disclosure may be a light-emitting diode including an organic material or may be a quantum dot light-emitting diode including a quantum dot. For example, an interlayer of the display element may include an organic material, an inorganic material, a quantum dot, an organic material and a quantum dot, or an inorganic material and a quantum dot.

The substrate 100 may include glass, quartz, or polymer resin. According to some embodiments, the substrate 100 may be flexible, foldable, rollable, or bendable. According to some embodiments, the substrate 100 may be a rigid substrate.

The pixel circuit layer PCL may be arranged on the substrate 100. The pixel circuit layer PCL may include the sub-pixel circuit PC, a connection wire CWL, and an insulating layer. The sub-pixel circuit PC may include a first sub-pixel circuit PC1, a second sub-pixel circuit PC2, and a third sub-pixel circuit PC3. According to some embodiments, as shown in FIG. 2A, the first sub-pixel circuit PC1 may be arranged in the third display region DA3. According to some embodiments, as shown in FIG. 2B, the first sub-pixel circuit PC1 may be arranged in the non-display region NDA. The second sub-pixel circuit PC2 may be arranged in the second display region DA2. The third sub-pixel circuit PC3 may be arranged in the third display region DA3. The sub-pixel circuit PC may not be arranged in the first display region DA1. The transmittance (for example, light transmittance) of the first display region DA1 may be relatively greater than the transmittance of the second display region DA2 and the third display region DA3.

According to some embodiments, a first display element DPE1 may be arranged in the first display region DA1 of the substrate 100 to implement the first sub-pixel PX1. According to some embodiments, as shown in FIG. 2A, the first sub-pixel circuit PC1 that drives the first display element DPE1 (or is electrically connected to the first display element DPE1) may not be arranged in the first display region DA1 and may be arranged in the third display region DA3 between the first display region DA1 and the second display region DA2. According to some embodiments, as shown in FIG. 2B, the first sub-pixel circuit PC1 configured to drive the first display element DPE1 may not be arranged in the third display region DA3 and may be arranged in the non-display region NDA. In other words, the first sub-pixel circuit PC1 may be arranged to not overlap the first display element DPE1.

The first sub-pixel circuit PC1 may include at least one thin-film transistor and may be electrically connected to the first display element DPE1 via the connection wire CWL. According to some embodiments, at least a portion of the connection wire CWL may include a metal or an alloy. The first sub-pixel circuit PC1 may be configured to control the operation of the first display element DPE1. The first sub-pixel PX1 may be implemented by emission of the first display element DPE1.

In the first display region DA1, a region in which the first display element DPE1 of the first sub-pixel PX1 is not arranged may be defined as the transmission region TA. The transmission region TA may be a region through which light/signals emitted from the component COM arranged to correspond to the first display region DA1 or light/signals incident on the component COM are transmitted.

The connection wire CWL that electrically connects the first sub-pixel circuit PC1 to the first display element DPE1 may be arranged in the transmission region TA.

According to some embodiments, a second display element DPE2 and the second sub-pixel circuit PC2 electrically connected to the second display element DPE2 may be arranged in the second display region DA2 of the substrate 100. The second sub-pixel circuit PC2 may include at least one thin-film transistor and may be configured to control the operation of the second display element DPE2. The second sub-pixel PX2 may be implemented by emission of the second display element DPE2.

According to some embodiments, a third display element DPE3 and the third sub-pixel circuit PC3 electrically connected to the third display element DPE3 may be arranged in the third display region DA3 of the substrate 100. The third sub-pixel circuit PC3 may include at least one thin-film transistor and may be configured to control the operation of the third display element DPE3. The third sub-pixel PX3 may be implemented by emission of the third display element DPE3. According to some embodiments, the first sub-pixel circuit PC1 and the third sub-pixel circuit PC3, which are arranged in the third display region DA3, may be adjacent to each other and may be arranged alternately.

The display element layer may be covered with the encapsulation layer 300 or may be covered with the sealing substrate, as shown in FIGS. 2A and 2B. According to some embodiments, the encapsulation layer 300 may include at least one inorganic encapsulation layer and at least one organic encapsulation layer. For example, the encapsulation layer 300 may include first and second inorganic encapsulation layers 310 and 330 and an organic encapsulation layer 320 arranged between the first and second inorganic encapsulation layers 310 and 330.

The touch screen layer TSL may obtain coordinate information according to an external input, for example, a touch event. The touch screen layer TSL may include a touch electrode and touch wires connected to the touch electrode. The touch screen layer TSL may detect an external input by using a self-capacitance method or a mutual capacitance method.

The touch screen layer TSL may be formed on the encapsulation layer 300. Alternatively, the touch screen layer TSL may be formed separately on a touch substrate and then bonded onto the encapsulation layer 300 via an adhesive layer such as an optically clear adhesive (OCA). According to some embodiments, the touch screen layer TSL may be directly formed on the encapsulation layer 300, and in this case, the adhesive layer may not be arranged between the touch screen layer TSL and the encapsulation layer 300.

The optical functional layer OFL may include a reflection prevention layer. The reflection prevention layer may reduce the reflectance of light (external light) incident on the electronic device DV from the outside. According to some embodiments, the optical functional layer OFL may be a polarizing film. According to some embodiments, the optical functional layer OFL may include an opening corresponding to the transmission region TA. Accordingly, the light transmittance of the transmission region TA may be significantly improved. The opening may be filled with a transparent material such as optically clear resin (OCR). According to some embodiments, the optical functional layer OFL may be provided as a filter plate including a black matrix and color filters.

The panel protection member PB may be arranged under the substrate 100. The panel protection member PB may support and protect the substrate 100. According to some embodiments, the panel protection member PB may include an opening PB_OP overlapping the first display region DA1. According to some embodiments, the opening PB_OP in the panel protection member PB may overlap the first display region DA1 and the third display region DA3. According to some embodiments, the panel protection member PB may include polyethylene terephthalate or polyimide.

According to some embodiments, the area of the opening PB_OP provided in the panel protection member PB may be greater than the area of the region in which the component COM is arranged. FIGS. 2A and 2B show that the component COM is arranged apart from one side of the display panel DP, but at least a portion of the component COM may be inserted into the opening PB_OP provided in the panel protection member PB.

The cover window may be arranged on the upper portion of the electronic device DV. The cover window may protect the electronic device DV, for example, the display panel DP. The cover window may include at least one of glass, sapphire, or plastic. The cover window may be, for example, ultra thin glass (UTG) or colorless polyimide (CPI).

The component COM may be arranged on the lower portion of the electronic device DV. According to some embodiments, the component COM may be arranged on a side opposite to the cover window with the display panel DP therebetween. According to some embodiments, the component COM may overlap the first display region DA1. According to some embodiments, the component COM may overlap the first display region DA1 and the third display region DA3. According to some embodiments, the first sub-pixel circuit PC1 configured to drive the first display element DPE1 arranged in the first display region DA1 may not be arranged in the first display region DA1 and may be arranged in the third display region DA3, and thus the transmittance (for example, light transmittance) of the first display region DA1 may be greater than the transmittance (for example, light transmittance) of the second display region DA2 and the third display region DA3.

The component COM may be provided as a single component or a plurality of components. A plurality of components COM may have different functions. For example, the components COM may include at least two of a camera (imaging device), a solar cell, a flash, a proximity sensor, an illuminance sensor, and an iris sensor.

In addition, as shown in FIGS. 2A and 2B, a bottom metal layer BML may be arranged under the sub-pixel circuit PC. The bottom metal layer BML may be arranged to overlap the sub-pixel circuit PC to protect the sub-pixel circuit PC. According to some embodiments, the bottom metal layer BML may be arranged between the substrate 100 corresponding to the third display region DA3 and the first sub-pixel circuit PC1 and/or the third sub-pixel circuit PC3 to overlap the first sub-pixel circuit PC1 and/or the third sub-pixel circuit PC3. The bottom metal layer BML may block external light from reaching the first sub-pixel circuit PC1 and/or the third sub-pixel circuit PC3. In addition, the bottom metal layer BML may be arranged under the second sub-pixel circuit PC2 in the second display region DA2. The bottom metal layer BML arranged under the second sub-pixel circuit PC2 may be arranged apart from the bottom metal layer BML arranged under the first sub-pixel circuit PC1 and/or the third sub-pixel circuit PC3. According to some embodiments, the bottom metal layer BML may be formed to correspond to the entire display region DA and may be provided to include a hole corresponding to the first display region DA1. According to some embodiments, the bottom metal layer BML may be omitted.

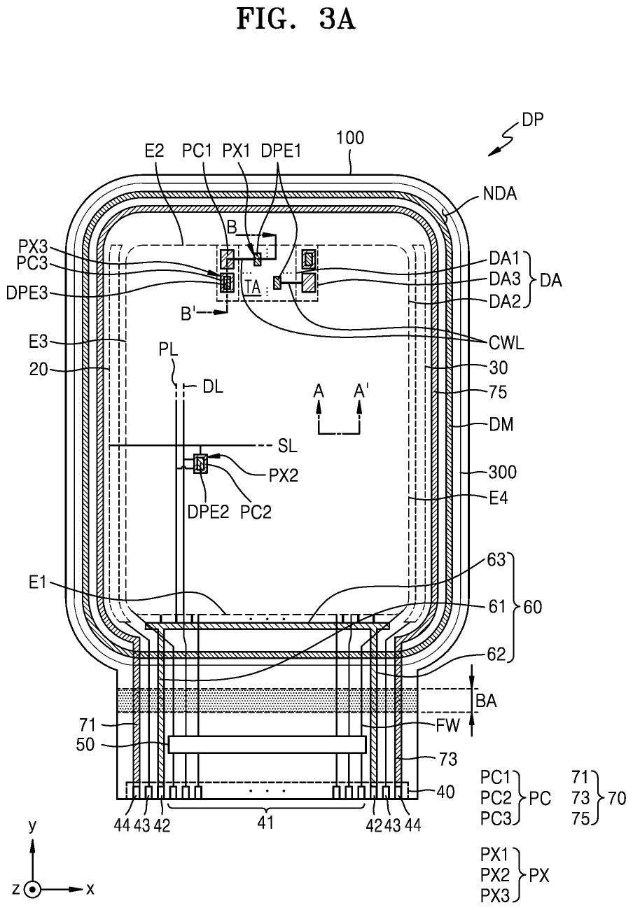

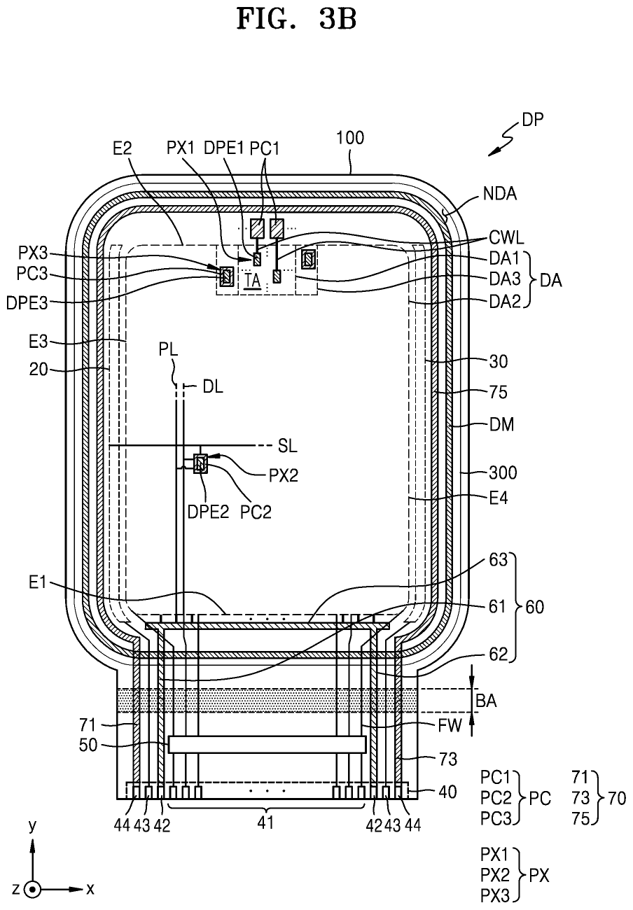

FIGS. 3A and 3B are each a plan view schematically showing the display panel DP according to some embodiments.

Referring to FIGS. 3A and 3B, the display panel DP may include first and second scan drivers 20 and 30 arranged on the substrate 100, a terminal portion 40, a data driver 50, and a power supply line. The power supply line may include a driving voltage supply line 60 and a common voltage supply line 70.

The substrate 100 may include the display region DA and the non-display region NDA outside the display region DA. A portion of the non-display region NDA may extend to one side (for example, in a −y direction). The terminal portion 40, the data driver 50, the driving voltage supply line 60, and a fan-out wire FW may be arranged on the extended non-display region NDA. According to some embodiments, the width of the extended non-display region NDA in an x-axis direction may be smaller than the width of the display region DA in an x-axis direction.

The substrate 100 may include a bending region BA in which a portion of the extended non-display region NDA is bent. Because the extended non-display region NDA is folded with respect to the bending region BA, the extended non-display region NDA may partially overlap the display region DA. Due to this structure, the extended non-display region NDA may not be visible to a user or, even when the extended non-display region NDA is visible, the visible area may be minimized or reduced.

The plurality of sub-pixels PX may be arranged in the display region DA. Each of sub-pixel circuits PC (for example, the first to third sub-pixel circuits PC1 to PC3), which are configured to drive the sub-pixels PX, may be connected to a signal line or voltage line for controlling on/off and luminance of a display element. For example, FIGS. 3A and 3B show, as signal lines, a scan line SL extending in the first direction (for example, x direction) and a data line DL and a driving voltage line PL, which extend in the second direction (for example, y direction).

The first display element DPE1 of the first sub-pixel PX1 may be arranged in the first display region DA1. According to some embodiments, as shown in FIG. 3A, the first sub-pixel circuit PC1 connected to the first display element DPE1 may be arranged in the third display region DA3 and may not overlap the first display element DPE1. According to some embodiments, as shown in FIG. 3B, the first sub-pixel circuit PC1 connected to the first display element DPE1 may be arranged in the non-display region NDA and may not overlap the first display element DPE1. In other words, in a plan view, the first sub-pixel circuit PC1 and the first display element DPE1 may be arranged apart from each other. The first sub-pixel circuit PC1 and the first display element DPE1 may be electrically connected to each other via the connection wire CWL.

The first sub-pixel circuit PC1 including transistors and a storage capacitor, which are connected to signal lines and voltage lines, may be arranged in the third display region DA3 or the non-display region NDA, and when the first display element DPE1 is arranged in the first display region DA1, the area of the transmission region TA may be increased while the resolution in the first display region DA1 is maintained.

The second display element DPE2 of the second sub-pixel PX2 may be arranged in the second display region DA2. The second sub-pixel circuit PC2 may be arranged in the second display region DA2 and may be arranged to overlap the second display element DPE2.

The third display element DPE3 of the third sub-pixel PX3 may be arranged in the third display region DA3. The third sub-pixel circuit PC3 may be arranged in the third display region DA3 and may be arranged to overlap the third display element DPE3.

Each of the first to third sub-pixel circuits PC1, PC2, and PC3 respectively configured to drive the first to third sub-pixels PX1, PX2, and PX3 may be electrically connected to external circuits arranged in the non-display region NDA. The first and second scan drivers 20 and 30, the terminal portion 40, the data driver 50, the driving voltage supply line 60, and the common voltage supply line 70 may be arranged in the non-display region NDA.

The first scan driver 20 and the second scan driver 30 may be configured to generate a scan signal and transmit the scan signal to each of the sub-pixel circuits PC (for example, the first to third sub-pixel circuits PC1 to PC3) via the scan line SL. According to some embodiments, either of the first scan driver 20 or the second scan driver 30 may apply an emission control signal to each of the sub-pixel circuits PC (for example, the first to third sub-pixel circuits PC1 to PC3) via an emission control line. According to some embodiments, the first and second scan drivers 20 and 30 may be arranged at opposite sides of the display region DA, but according to some embodiments, a scan driver may be arranged at only one side of the display region DA. The second scan driver 30 may be arranged symmetrically with the first scan driver 20, with respect to the display region DA.

The data driver 50 may generate a data signal and transmit the data signal to each of the sub-pixel circuits PC (for example, the first to third sub-pixel circuits PC1 to PC3) via the data line DL. The data driver 50 may be arranged on one side of the display region DA, and may be arranged in the extended non-display region NDA at a lower side (for example, −y direction) of the display region DA. FIGS. 3A and 3B show that the data driver 50 is arranged on the substrate 100, but according to some embodiments, the data driver 50 may be provided on a flexible printed circuit board connected to the terminal portion 40.

The terminal portion 40 is arranged at one end of the substrate 100 and includes a plurality of terminals 41, 42, 43, and 44. The terminal portion 40 may be exposed without being covered by an insulating layer and may be electrically connected to a controller such as a flexible printed circuit board or an IC chip. Control signals of the controller may be respectively provided to the first scan driver 20, the second scan driver 30, the data driver 50, the driving voltage supply line 60, and the common voltage supply line 70 via the terminal portion 40.

The driving voltage supply line 60 may be arranged in the non-display region NDA. The driving voltage supply line 60 may be configured to provide a driving voltage ELVDD to each of the sub-pixels PX. According to some embodiments, the driving voltage supply line 60 may include a first driving voltage supply line 61, a second driving voltage supply line 62, and a third driving voltage supply line 63. The third driving voltage supply line 63 may extend in the first direction (for example, x direction), and the first and second driving voltage supply lines 61 and 62 may extend in the second direction (for example, y direction). For example, the third driving voltage supply line 63 may be arranged along a first edge E1 of the display region DA. According to some embodiments, the first driving voltage supply line 61, the second driving voltage supply line 62, and the third driving voltage supply line 63 may be integrally formed as a single body. For example, the driving voltage supply line 60 may have a “IT” (pi) shape as a single body. However, embodiments according to the present disclosure are not limited thereto.

The driving voltage supply line 60 may be arranged in the non-display region NDA and may be connected to a plurality of driving voltage lines PL extending to the display region DA in the second direction (for example, y direction). For example, the third driving voltage supply line 63 may be connected to the driving voltage line PL that crosses the display region DA in the second direction (for example, y direction).

The common voltage supply line 70 may be arranged in the non-display region NDA and may be configured to provide a common voltage ELVSS to each of the sub-pixels PX. The common voltage supply line 70 may include a first common voltage supply line 71 and a second common voltage supply line 73, which are arranged adjacent to the first edge E1 of the display region DA. The first common voltage supply line 71 and the second common voltage supply line 73 may extend in the second direction (for example, y direction). In addition, the first common voltage supply line 71 and the second common voltage supply line 73 may be arranged apart from each other in the first direction (for example, x direction) crossing the second direction (for example, y direction). The first common voltage supply line 71 and the second common voltage supply line 73 may be respectively arranged on opposite sides of the first edge E1 of the display region DA. However, embodiments according to the present disclosure are not limited thereto. The common voltage supply line 70 may further include a third common voltage supply line arranged between the first common voltage supply line 71 and the second common voltage supply line 73. In a case where the common voltage supply line 70 includes the third common voltage supply line arranged between the first common voltage supply line 71 and the second common voltage supply line 73, compared to a case where only the first common voltage supply line 71 and the second common voltage supply line 73 are provided, the current density may be reduced and heat generation may be suppressed when current is applied.

The first common voltage supply line 71 and the second common voltage supply line 73 may be connected to each other by a body portion 75 extending along a second edge E2, a third edge E3, and a fourth edge E4 of the display region DA. According to some embodiments, the first common voltage supply line 71, the second common voltage supply line 73, and the body portion 75 may be integrally formed as a single body.

In addition, a dam DM may be arranged in the non-display region NDA. The dam DM may be arranged to surround the outside of the display region DA. The dam DM may be arranged outside the common voltage supply line 70 or may be arranged to partially overlap the common voltage supply line 70.

The encapsulation layer 300 may be arranged to cover the sub-pixels PX in the display region DA, and a portion of the encapsulation layer 300 may extend to the non-display region NDA. The encapsulation layer 300 may have a multilayer structure including at least one organic encapsulation layer and at least one inorganic encapsulation layer, and the dam DM may prevent or reduce instances of a material for forming an organic encapsulation layer included in the encapsulation layer 300 spreading toward an edge of the substrate 100 and may limit a formation location of the organic encapsulation layer.

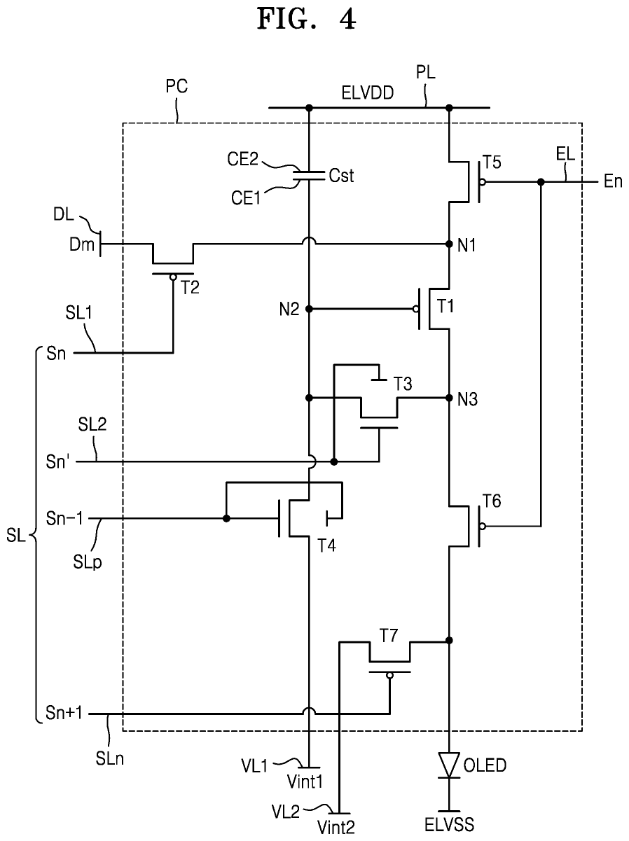

FIG. 4 is an equivalent circuit diagram schematically showing the sub-pixel circuit PC electrically connected to a light-emitting diode corresponding to one sub-pixel arranged on a display panel according to some embodiments. Although FIG. 4 illustrates various components in the sub-pixel circuit PC according to some embodiments, embodiments according to the present disclosure are not limited thereto, and according to various embodiments, the sub-pixel circuit PC may include additional components, or fewer components, without departing from the spirit and scope of embodiments according to the present disclosure.

The sub-pixel circuit PC shown in FIG. 4 may correspond to each of the first sub-pixel circuit PC1, the second sub-pixel circuit PC2, and the third sub-pixel circuit PC3, which have been described with reference to FIGS. 3A and 3B.

An organic light-emitting diode OLED which is a display element shown in FIG. 4 may correspond to each of the first display element DPE1, the second display element DPE2, and the third display element DPE3, which have been described with reference to FIGS. 3A and 3B.

Referring to FIG. 4, the sub-pixel circuit PC may include a plurality of thin-film transistors T1 to T7 and a storage capacitor Cst. The plurality of thin-film transistors T1 to T7 and the storage capacitor Cst may be connected to signal lines SL1, SL2, SLp, SLn, EL, and DL, a first initialization voltage line VL1, a second initialization voltage line VL2, and the driving voltage line PL. At least any one of these wires, for example, the driving voltage line PL, may be shared by neighboring sub-pixel circuits PC.

According to some embodiments, the plurality of thin-film transistors T1 to T7 may include a driving transistor T1, a switching transistor T2, a compensation transistor T3, a first initialization transistor T4, an operation control transistor T5, a light-emission control transistor T6, and a second initialization transistor T7. However, embodiments according to the present disclosure are not limited thereto.

The organic light-emitting diode OLED may include a pixel electrode and an opposite electrode, wherein the pixel electrode of the organic light-emitting diode OLED may be connected to the driving transistor T1 via the light-emission control transistor T6 to receive a driving current, and the opposite electrode may receive the common voltage ELVSS. The organic light-emitting diode OLED may generate light of luminance corresponding to the driving current.

Some of the plurality of thin-film transistors T1 to T7 may be n-channel MOSFET (NMOS) transistors, and the others may be p-channel MOSFET (PMOS) transistors. For example, among the plurality of thin-film transistors T1 to T7, the compensation transistor T3 and the first initialization transistor T4 may be NMOS transistors, and the others may be PMOS transistors. Alternatively, among the plurality of thin-film transistors T1 to T7, the compensation transistor T3, the first initialization transistor T4, and the second initialization transistor T7 may be NMOS transistors, and the others may be PMOS transistors. Alternatively, all of the plurality of thin-film transistors T1 to T7 may be NMOS transistors or PMOS transistors. The plurality of thin-film transistors T1 to T7 may include amorphous silicon or polysilicon. As necessary, an NMOS transistor may include an oxide semiconductor. Hereinafter, for convenience, a case where the compensation transistor T3 and the first initialization transistor T4 are NMOS transistors including an oxide semiconductor and the others are PMOS transistors is described.

The signal lines may include a first scan line SL1, a second scan line SL2, a previous scan line SLp, a subsequent scan line SLn, a light-emission control line EL, and the data line DL. However, embodiments according to the present disclosure are not limited thereto. In addition, the first scan line SL1 may be configured to transmit a first scan signal Sn. The second scan line SL2 may be configured to transmit a second scan signal Sn′. The previous scan line SLp may be configured to transmit a previous scan signal Sn-1 to the first initialization transistor T4. The subsequent scan line SLn may be configured to transmit a subsequent scan signal Sn+1 to the second initialization transistor T7. The light-emission control line EL may be configured to transmit a light-emission control signal En to the operation control transistor T5 and the light-emission control transistor T6. The data line DL may be configured to transmit a data signal Dm.

The driving voltage line PL may be configured to transmit the driving voltage ELVDD to the driving transistor T1, the first initialization voltage line VL1 may be configured to transmit a first initialization voltage Vint1 that initializes the driving transistor T1, and the second initialization voltage line VL2 may be configured to transmit a second initialization voltage Vint2 that initializes the pixel electrode of the organic light-emitting diode OLED.

A driving gate electrode of the driving transistor T1 may be connected to the storage capacitor Cst via a second node N2, any one of a source region and a drain region of the driving transistor T1 may be connected to the driving voltage line PL via the operation control transistor T5 via a first node N1, and the other one of the source region and the drain region of the driving transistor T1 may be electrically connected to the pixel electrode of the organic light-emitting diode OLED via the light-emission control transistor T6 via a third node N3. The driving transistor T1 may be configured to receive the data signal Dm according to a switching operation of the switching transistor T2 and supply a driving current to the organic light-emitting diode OLED. In other words, the driving transistor T1 may be configured to control the amount of current flowing from the first node N1, which is electrically connected to the driving voltage line PL, to the organic light-emitting diode OLED in accordance with a voltage applied to the second node N2, which varies depending on the data signal Dm.

A switching gate electrode of the switching transistor T2 may be connected to the first scan line SL1 configured to transmit the first scan signal Sn, one of a source region and a drain region of the switching transistor T2 may be connected to the data line DL, and the other one of the source region and the drain region of the switching transistor T2 may be connected to the driving transistor T1 via the first node N1 and connected to the driving voltage line PL via the operation control transistor T5. The switching transistor T2 may be configured to transmit, to the first node N1, the data signal Dm from the data line DL in accordance with a voltage applied to the first scan line SL1. In other words, the switching transistor T2 may be turned on according to the first scan signal Sn, which is received via the first scan line SL1, to perform a switching operation to transmit the data signal Dm, which is transmitted to the data line DL, to the driving transistor T1 via the first node N1.

A compensation gate electrode of the compensation transistor T3 is connected to the second scan line SL2. One of a source region and a drain region of the compensation transistor T3 may be connected to the pixel electrode of the organic light-emitting diode OLED via the light-emission control transistor T6 via the third node N3. The other one of the source region and the drain region of the compensation transistor T3 may be connected to a first capacitor electrode CE1 of the storage capacitor Cst and the driving gate electrode of the driving transistor T1 via the second node N2. The compensation transistor T3 may be turned on according to the second scan signal Sn′, which is received via the second scan line SL2, to diode-connect the driving transistor T1.

A first initialization gate electrode of the first initialization transistor T4 may be connected to the previous scan line SLp. One of a source region and a drain region of the first initialization transistor T4 may be connected to the first initialization voltage line VL1. The other one of the source region and the drain region of the first initialization transistor T4 may be connected to the first capacitor electrode CE1 of the storage capacitor Cst and the driving gate electrode of the driving transistor T1 via the second node N2. The first initialization transistor T4 may be configured to apply, to the second node N2, the first initialization voltage Vint1 from the first initialization voltage line VL1 in accordance with a voltage applied to the previous scan line SLp. In other words, the first initialization transistor T4 may be turned on according to the previous scan signal Sn-1, which is received via the previous scan line SLp, to transmit the first initialization voltage Vint1 to the driving gate electrode of the driving transistor T1 and perform an initialization operation to initialize a voltage of the driving gate electrode of the driving transistor T1.

An operation control gate electrode of the operation control transistor T5 may be connected to the light-emission control line EL, one of a source region and a drain region of the operation control transistor T5 may be connected to the driving voltage line PL, and the other one may be connected to the driving transistor T1 and the switching transistor T2 via the first node N1.

A light-emission control gate electrode of the light-emission control transistor T6 may be connected to the light-emission control line EL, one of a source region and a drain region of the light-emission control transistor T6 may be connected to the driving transistor T1 and the compensation transistor T3 via the third node N3, and the other one of the source region and the drain region of the light-emission control transistor T6 may be electrically connected to the pixel electrode of the organic light-emitting diode OLED.

The operation control transistor T5 and the light-emission control transistor T6 may be simultaneously turned on according to the light-emission control signal En, which is received via the light-emission control line EL, to transmit the driving voltage ELVDD to the organic light-emitting diode OLED, thereby allowing a driving current to flow through the organic light-emitting diode OLED.

A second initialization gate electrode of the second initialization transistor T7 may be connected to the subsequent scan line SLn, one of a source region and a drain region of the second initialization transistor T7 may be connected to the pixel electrode of the organic light-emitting diode OLED, and the other one of the source region and the drain region of the second initialization transistor T7 may be connected to the second initialization voltage line VL2 to receive the second initialization voltage Vint2. The second initialization transistor T7 may be turned on according to the subsequent scan signal Sn+1, which is received via the subsequent scan line SLn, to initialize the pixel electrode of the organic light-emitting diode OLED. The subsequent scan line SLn may be the same as the first scan line SL1. In this case, the corresponding scan line may be configured to transmit a same electrical signal with a time difference and may be configured to function as the first scan line SL1 or the subsequent scan line SLn. In other words, the subsequent scan line SLn may be adjacent to the sub-pixel circuit PC shown in FIG. 4, but may be a first scan line of another sub-pixel circuit electrically connected to the same data line DL.

The storage capacitor Cst may include the first capacitor electrode CE1 and a second capacitor electrode CE2. The first capacitor electrode CE1 of the storage capacitor Cst may be connected to the driving gate electrode of the driving transistor T1 via the second node N2, and the second capacitor electrode CE2 of the storage capacitor Cst may be connected to the driving voltage line PL. The storage capacitor Cst may store a charge corresponding to a difference between a voltage of the driving gate electrode of the driving transistor T1 and the driving voltage ELVDD.

Specific operations of the sub-pixel circuit PC and the organic light-emitting diode OLED, which is a display element, according to some embodiments are as follows.

During an initialization period, when the previous scan signal Sn-1 is supplied via the previous scan line SLp, the first initialization transistor T4 may be turned on in accordance with the previous scan signal Sn-1, and the driving transistor T1 may be initialized by the first initialization voltage Vint1 supplied from the first initialization voltage line VL1.

During a data programming period, when the first scan signal Sn and the second scan signal Sn′ are supplied via the first scan line SL1 and the second scan line SL2, the switching transistor T2 and the compensation transistor T3 may be turned on in accordance with the first scan signal Sn and the second scan signal Sn′. At this time, the driving transistor T1 may be diode-connected by the turned-on compensation transistor T3 and forward biased. Then, a compensation voltage (Dm+Vth, where Vth has a (−) value), which is obtained by reducing the data signal Dm supplied from the data line DL by a threshold voltage (Vth) of the driving transistor T1, may be applied to the driving gate electrode of the driving transistor T1. The driving voltage ELVDD and the compensation voltage (Dm+Vth) are applied to respective ends of the storage capacitor Cst, and a charge corresponding to a difference between voltages at both ends is stored in the storage capacitor Cst.

During a light-emission period, the operation control transistor T5 and the light-emission control transistor T6 may be turned on by the light-emission control signal En supplied from the light-emission control line EL. A driving current may be generated according to a difference between a voltage of the driving gate electrode of the driving transistor T1 and the driving voltage ELVDD, and the driving current may be supplied to the organic light-emitting diode OLED via the light-emission control transistor T6.

As described above, some of the plurality of thin-film transistors T1 to T7 may include an oxide semiconductor. For example, the compensation transistor T3 and the first initialization transistor T4 may include an oxide semiconductor. However, embodiments according to the present disclosure are not limited thereto.

The sub-pixel circuit PC is not limited to the number and circuit design of thin-film transistors and capacitors described with reference to FIG. 4, and the number and circuit design may be changed in various ways.

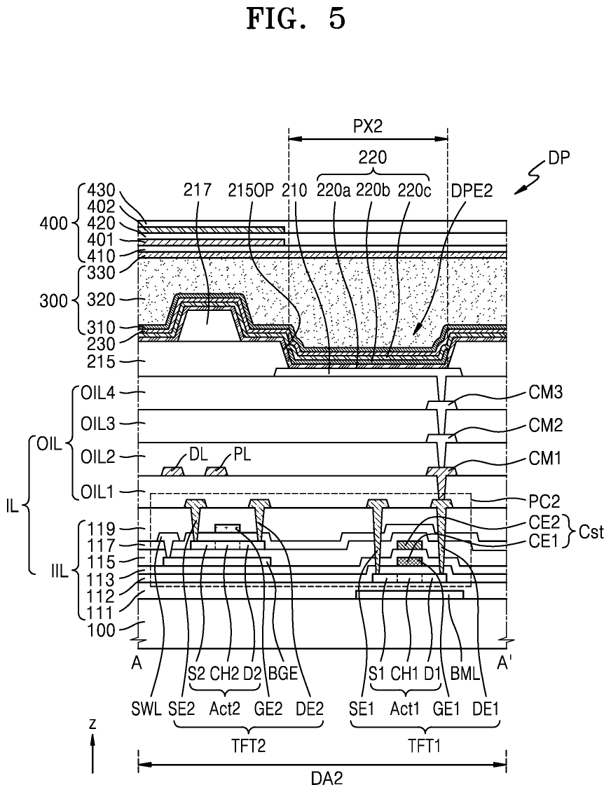

FIG. 5 is a cross-sectional view showing a structure of the display panel DP in the second display region DA2, according to some embodiments, and is a cross-sectional view of the display panel DP of FIG. 3A taken along a line A-A′ shown in FIG. 3A.

Referring to FIG. 5, the display panel DP may include the substrate 100, a display portion, the encapsulation layer 300, and a touch sensor layer 400. The display portion may include an insulating layer IL, the second sub-pixel circuit PC2, the second display element DPE2, and a bank layer 215.

The substrate 100 may be glass or may include polymer resin such as polyethersulfone, polyarylate, polyether imide, polyethylene naphthalate, polyethylene terephthalate, polyphenylene sulfide, polyimide, polycarbonate, cellulose triacetate, cellulose acetate propionate, etc. According to some embodiments, the substrate 100 may have a multilayer structure including a base layer, which includes polymer resin described above, and a barrier layer. The substrate 100 including polymer resin may be flexible, rollable, and bendable.

The insulating layer IL may be arranged on the substrate 100. The insulating layer IL may include an inorganic insulating layer IIL and an organic insulating layer OIL. According to some embodiments, the inorganic insulating layer IIL may include a buffer layer 111, a first gate insulating layer 112, a second gate insulating layer 113, a first interlayer insulating layer 115, a third gate insulating layer 117, and a second interlayer insulating layer 119.

The second sub-pixel circuit PC2 may be arranged in the second display region DA2. The second sub-pixel circuit PC2 may include a plurality of transistors and a storage capacitor, as described with reference to FIG. 4. In this regard, FIG. 5 shows a first thin-film transistor TFT1, a second thin-film transistor TFT2, and the storage capacitor Cst. The first thin-film transistor TFT1 may include a first semiconductor layer Act1, a first gate electrode GE1, a first source electrode SE1, and a first drain electrode DE1. The second thin-film transistor TFT2 may include a second semiconductor layer Act2, a second gate electrode GE2, a second source electrode SE2, and a second drain electrode DE2. The storage capacitor Cst may include the first capacitor electrode CE1 and the second capacitor electrode CE2.

The buffer layer 111 may be arranged on the substrate 100. The buffer layer 111 may reduce or block penetration of foreign substances, moisture, or external air from under the substrate 100. The buffer layer 111 may include an inorganic material such as silicon oxide, silicon oxynitride, or silicon nitride, and may have a single layer or a multilayer, each including the above-described material.

The first semiconductor layer Act1 may include a silicon semiconductor. The first semiconductor layer Act1 may include polysilicon. Alternatively, the first semiconductor layer Act1 may include amorphous silicon. In some embodiments, the first semiconductor layer Act1 may include an oxide semiconductor or an organic semiconductor. The first semiconductor layer Act1 may include a channel region CH1, a drain region D1, and a source region S1, wherein the drain region D1 and the source region S1 are respectively arranged at opposite sides of the channel region CH1. The first gate electrode GE1 may overlap the channel region CH1.

The first gate electrode GE1 may overlap the first semiconductor layer Act1. The first gate electrode GE1 may include a low-resistance metal material. The first gate electrode GE1 may include a conductive material including molybdenum (Mo), aluminum (Al), copper (Cu), titanium (Ti), etc., and may be a multilayer or a single layer, each including the above material.

The first gate insulating layer 112 may be arranged between the first semiconductor layer Act1 and the first gate electrode GE1. Therefore, the first semiconductor layer Act1 may be insulated from the first gate electrode GE1. The first gate insulating layer 112 may include an inorganic insulating material such as silicon oxide, silicon nitride, silicon oxynitride, aluminum oxide, titanium oxide, tantalum oxide, hafnium oxide, and/or zinc oxide.

The second gate insulating layer 113 may cover the first gate electrode GE1. The second gate insulating layer 113 may be arranged on the first gate electrode GE1. Similar to the first gate insulating layer 112, the second gate insulating layer 113 may include an inorganic insulating material such as silicon oxide, silicon nitride, silicon oxynitride, aluminum oxide, titanium oxide, tantalum oxide, hafnium oxide, and/or zinc oxide.

The second capacitor electrode CE2 may be arranged on the second gate insulating layer 113. The second capacitor electrode CE2 may overlap the first gate electrode GE1 thereunder. In this case, the second capacitor electrode CE2 and the first gate electrode GE1 may overlap each other with the second gate insulating layer 113 therebetween, thereby forming the storage capacitor Cst. In other words, the first gate electrode GE1 of the first thin-film transistor TFT1 may function as the first capacitor electrode CE1 of the storage capacitor Cst.

As such, the storage capacitor Cst and the first thin-film transistor TFT1 may overlap each other. In some embodiments, the storage capacitor Cst may not overlap the first thin-film transistor TFT1.

The second capacitor electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or a multilayer, each including the above-described material.

The first interlayer insulating layer 115 may cover the second capacitor electrode CE2. According to some embodiments, the first interlayer insulating layer 115 may cover the first gate electrode GE1. The first interlayer insulating layer 115 may include silicon oxide, silicon nitride, silicon oxynitride, aluminum oxide, titanium oxide, tantalum oxide, hafnium oxide, or zinc oxide. The first interlayer insulating layer 115 may be a single layer or a multilayer, each including the above-described inorganic insulating material.

The second semiconductor layer Act2 may be arranged on the first interlayer insulating layer 115. According to some embodiments, the second semiconductor layer Act2 may include a channel region CH2, a source region S2, and a drain region D2, wherein the source region S2 and the drain region D2 are respectively arranged at opposite sides of the channel region CH2. The second semiconductor layer Act2 may include an oxide semiconductor. For example, the second semiconductor layer Act2 may include Zn oxide, In—Zn oxide, or Ga—In—Zn oxide, as a Zn-oxide-based material. Alternatively, the second semiconductor layer Act2 may be an In—Ga—Zn—O (IGZO), In—Sn—Zn—O (ITZO), or In—Ga—Sn—Zn—O (IGTZO) semiconductor containing a metal such as indium (In), gallium (Ga), or tin (Sn) in zin oxide (ZnO).

The source region S2 and the drain region D2 of the second semiconductor layer Act2 may be formed by adjusting carrier concentration of the oxide semiconductor to make the oxide semiconductor conductive. For example, the source region S2 and the drain region D2 of the second semiconductor layer Act2 may be formed by increasing carrier concentration via plasma treatment using hydrogen-based gas, fluorine-based gas, or a combination thereof on the oxide semiconductor.

The third gate insulating layer 117 may cover the second semiconductor layer Act2. The third gate insulating layer 117 may be arranged between the second semiconductor layer Act2 and the second gate electrode GE2. According to some embodiments, the third gate insulating layer 117 may be arranged entirely on the substrate 100. According to some embodiments, the third gate insulating layer 117 may be patterned according to the shape of the second gate electrode GE2. The third gate insulating layer 117 may include silicon oxide, silicon nitride, silicon oxynitride, aluminum oxide, titanium oxide, tantalum oxide, hafnium oxide, or zinc oxide. The third gate insulating layer 117 may be a single layer or a multilayer, each including the above-described inorganic insulating material.

The second gate electrode GE2 may be arranged on the third gate insulating layer 117. The second gate electrode GE2 may overlap the second semiconductor layer Act2. The second gate electrode GE2 may overlap the channel region CH2 of the second semiconductor layer Act2. The second gate electrode GE2 may include a conductive material including molybdenum (Mo), aluminum (Al), copper (Cu), titanium (Ti), etc., and may be formed as a multilayer or a single layer, each including the above material.

The second interlayer insulating layer 119 may cover the second gate electrode GE2. The second interlayer insulating layer 119 may include silicon oxide, silicon nitride, silicon oxynitride, aluminum oxide, titanium oxide, tantalum oxide, hafnium oxide, or zinc oxide. The second interlayer insulating layer 119 may be a single layer or a multilayer, each including the above-described inorganic insulating material.

The first source electrode SE1 and the first drain electrode DE1 may be arranged on the second interlayer insulating layer 119. The first source electrode SE1 and the first drain electrode DE1 may be connected to the first semiconductor layer Act1. The first source electrode SE1 and the first drain electrode DE1 may be connected to the first semiconductor layer Act1 via contact holes in insulating layers.

The second source electrode SE2 and the second drain electrode DE2 may be arranged on the second interlayer insulating layer 119. The second source electrode SE2 and the second drain electrode DE2 may be electrically connected to the second semiconductor layer Act2. The second source electrode SE2 and the second drain electrode DE2 may be electrically connected to the second semiconductor layer Act2 via contact holes in insulating layers.

The first source electrode SE1, the first drain electrode DE1, the second source electrode SE2, and the second drain electrode DE2 may include a material exhibiting excellent conductivity. The first source electrode SE1, the first drain electrode DE1, the second source electrode SE2, and the second drain electrode DE2 may include a conductive material including molybdenum (Mo), aluminum (Al), copper (Cu), titanium (Ti), etc., and may be formed as a single layer or a multilayer, each including the above material. According to some embodiments, the first source electrode SE1, the first drain electrode DE1, the second source electrode SE2, and the second drain electrode DE2 may have a multilayer structure of Ti/Al/Ti.

The first thin-film transistor TFT1 including the first semiconductor layer Act1 including a silicon semiconductor may have high reliability. For example, the first thin-film transistor TFT1 may be the driving transistor T1 (FIG. 4). In this case, a high-quality display panel DP may be implemented.

Oxide semiconductors have high carrier mobility and low leakage current, and thus, there may be no significant voltage drop even when a driving time is long. In other words, there is no significant color change in an image due to voltage drop even during low-frequency driving, and thus, low-frequency driving is possible. As such, oxide semiconductors have low leakage current, and thus, leakage current may be prevented or reduced and power consumption may be relatively reduced at the same time, by employing an oxide semiconductor in at least one of other thin-film transistors other than the driving transistor. For example, the second thin-film transistor TFT2 may be the compensation transistor T3 (FIG. 4).

A lower gate electrode BGE may be arranged under the second semiconductor layer Act2. According to some embodiments, the lower gate electrode BGE may be arranged between the second gate insulating layer 113 and the first interlayer insulating layer 115. According to some embodiments, the lower gate electrode BGE may receive a gate signal. In this case, the second thin-film transistor TFT2 may include a double gate electrode structure in which gate electrodes are arranged above and under the second semiconductor layer Act2.

According to some embodiments, a sub-wire SWL may be arranged between the third gate insulating layer 117 and the second interlayer insulating layer 119. According to some embodiments, the sub-wire SWL may be electrically connected to the lower gate electrode BGE via a contact hole provided in the first interlayer insulating layer 115 and the third gate insulating layer 117.

According to some embodiments, the bottom metal layer BML may be arranged between the substrate 100 and the second sub-pixel circuit PC2 overlapping the second display region DA2. According to some embodiments, the bottom metal layer BML may overlap the first thin-film transistor TFT1. A constant voltage may be applied to the bottom metal layer BML. Because the bottom metal layer BML is arranged under the first thin-film transistor TFT1, the first thin-film transistor TFT1 may be less affected by surrounding interference signals and thus may have relatively improved reliability.

The organic insulating layer OIL may be arranged on the inorganic insulating layer IIL. The organic insulating layer OIL may include a first organic insulating layer OIL1, a second organic insulating layer OIL2, a third organic insulating layer OIL3, and a fourth organic insulating layer OIL4. However, embodiments according to the present disclosure are not limited thereto. The organic insulating layer OIL may include the first organic insulating layer OIL1 and the second organic insulating layer OIL2 or may include the first organic insulating layer OIL1, the second organic insulating layer OIL2, and the third organic insulating layer OIL3. In other words, the organic insulating layer OIL may include two or three layers instead of four layers.

The first organic insulating layer OIL1 may cover the first source electrode SE1, the first drain electrode DE1, the second source electrode SE2, and the second drain electrode DE2. The first organic insulating layer OIL1 may include an organic material. For example, the first organic insulating layer OIL1 may include an organic insulating material, such as a general purpose polymer, such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof.

A first connection electrode CM1, the data line DL, and the driving voltage line PL may be arranged on the first organic insulating layer OIL1. The first connection electrode CM1 may be connected to the first drain electrode DE1 or the first source electrode SE1 via a contact hole in the first organic insulating layer OIL1.

The first connection electrode CM1, the data line DL, and the driving voltage line PL may include a material exhibiting excellent conductivity. The first connection electrode CM1, the data line DL, and the driving voltage line PL may include a conductive material including molybdenum (Mo), aluminum (Al), copper (Cu), titanium (Ti), etc., and may be formed as a multilayer or a single layer, each including the above material. For example, the first connection electrode CM1, the data line DL, and the driving voltage line PL may have a multilayer structure of Ti/Al/Ti.

FIG. 5 shows that the data line DL and the driving voltage line PL are arranged on a same layer (for example, the first organic insulating layer OIL1), but according to some embodiments, the data line DL and the driving voltage line PL may be arranged on different layers from each other.

The second organic insulating layer OIL2 may cover the first connection electrode CM1, the data line DL, and the driving voltage line PL. The second organic insulating layer OIL2 may include an organic insulating material such as acryl, benzocyclobutene (BCB), polyimide, or hexamethyldisiloxane (HMDSO).

A second connection electrode CM2 may be arranged on the second organic insulating layer OIL2. At this time, the second connection electrode CM2 may be electrically connected to the first connection electrode CM1 via a contact hole defined in the second organic insulating layer OIL2.

The second connection electrode CM2 may include a material exhibiting excellent conductivity. The second connection electrode CM2 may include a conductive material including, for example, molybdenum (Mo), aluminum (Al), copper (Cu), titanium (Ti), etc. Alternatively, the second connection electrode CM2 may include a transparent conductive material, for example, a transparent conducting oxide (TCO). The second connection electrode CM2 may be formed as a multilayer or a single layer, each including the above-described material. According to some embodiments, the second connection electrode CM2 may have a multilayer structure of Ti/Al/Ti.

The third organic insulating layer OIL3 may cover the second connection electrode CM2. The third organic insulating layer OIL3 may include an organic material. According to some embodiments, the third organic insulating layer OIL3 may include an organic insulating material such as acryl, BCB, polyimide, or HMDSO.

A third connection electrode CM3 may be arranged on the third organic insulating layer OIL3. At this time, the third connection electrode CM3 may be electrically connected to the second connection electrode CM2 via a contact hole defined in the third organic insulating layer OIL3.

The third connection electrode CM3 may include a material exhibiting excellent conductivity. The third connection electrode CM3 may include a conductive material including molybdenum (Mo), aluminum (Al), copper (Cu), titanium (Ti), etc. Alternatively, the third connection electrode CM3 may include a transparent conductive material, for example, a transparent conducting oxide (TCO). The third connection electrode CM3 may be formed as a multilayer or a single layer, each including the above-described material. According to some embodiments, the third connection electrode CM3 may have a multilayer structure of Ti/Al/Ti.

A fourth organic insulating layer OIL4 may cover the third connection electrode CM3. The fourth organic insulating layer OIL4 may include an organic material. According to some embodiments, the fourth organic insulating layer OIL4 may include an organic insulating material such as acryl, BCB, polyimide, or HMDSO.

The second display element DPE2 arranged in the second display region DA2 may be arranged on the organic insulating layer OIL. The second display element DPE2 may be an organic light-emitting diode. For example, the second display element DPE2 may be arranged on the fourth organic insulating layer OIL4.

The second display element DPE2 may be electrically connected to the second sub-pixel circuit PC2. In the second display region DA2, the second display element DPE2 may be electrically connected to the second sub-pixel circuit PC2 to implement the second sub-pixel PX2. The second display element DPE2 may overlap the second sub-pixel circuit PC2. The second display element DPE2 is an organic light-emitting diode and may include a pixel electrode 210, an intermediate layer 220, and an opposite electrode 230.

The pixel electrode 210 may be arranged on the fourth organic insulating layer OIL4. The pixel electrode 210 may be electrically connected to the third connection electrode CM3 via a contact hole defined in the fourth organic insulating layer OIL4.

The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. Alternatively, the pixel electrode 210 may further include a conductive oxide layer above and/or under the above-described reflective film. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). According to some embodiments, the pixel electrode 210 may have a three-layer structure of ITO/Ag/ITO.

The bank layer 215 may be arranged on the pixel electrode 210. An opening 215OP through which at least a portion of the pixel electrode 210 is exposed may be defined in the bank layer 215. A central portion of the pixel electrode 210 may be exposed via the opening 215OP defined in the bank layer 215. The opening 215OP may define an emission region of light emitted from the second display element DPE2.

The bank layer 215 may include an organic insulating material. According to some embodiments, the bank layer 215 may include an inorganic insulating material such as silicon nitride, silicon oxynitride, or silicon oxide. According to some embodiments, the bank layer 215 may include an organic insulating material and an inorganic insulating material. In some embodiments, the bank layer 215 may include a light-blocking material and may be black. The light-blocking material may include resin or paste including carbon black, carbon nanotubes, or black dye, metal particles such as nickel, aluminum, molybdenum, and alloys thereof, metal oxide particles (for example, chromium oxide), or metal nitride particles (for example, chromium nitride). When the bank layer 215 includes a light-blocking material, reflection of external light by metal structures arranged under the bank layer 215 may be reduced.

A spacer 217 may be formed on the bank layer 215. The spacer 217 and the bank layer 215 may be formed together in a same process or may be formed individually in separate processes. According to some embodiments, the spacer 217 may include an organic insulating material such as polyimide.

The intermediate layer 220 includes an emission layer 220b. The intermediate layer 220 may include a first common layer 220a arranged under the emission layer 220b and/or a second common layer 220c arranged above the emission layer 220b. The emission layer 220b may include a polymer or low-molecular-weight organic material that emits light of a certain color (red, green, or blue). According to some embodiments, the emission layer 220b may include an inorganic material or a quantum dot.

The first common layer 220a may include a hole transport layer (HTL) and/or a hole injection layer (HIL). The second common layer 220c may include an electron transport layer (ETL) and/or an electron injection layer (EIL). The first common layer 220a and the second common layer 220c may include an organic material.

The emission layer 220b may be formed in the second display region DA2 to overlap the pixel electrode 210 via the opening 215OP in the bank layer 215. In contrast, an organic material layer, for example, the first common layer 220a and the second common layer 220c, included in the intermediate layer 220 may entirely cover the second display region DA2.

The intermediate layer 220 may have a single stack structure including a single emission layer or may have a tandem structure which is a multi-stack structure including a plurality of emission layers. When the intermediate layer 220 has a tandem structure, a charge generation layer (CGL) may be arranged between a plurality of stacks.

The opposite electrode 230 may be arranged on the intermediate layer 220. The opposite electrode 230 may include a conductive material having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or alloys thereof. Alternatively, the opposite electrode 230 may further include a layer including ITO, IZO, ZnO, or In₂O₃ on the (semi) transparent layer including the above-described material. According to some embodiments, the opposite electrode 230 may entirely cover the second display region DA2.

The second display element DPE2 may be covered with the encapsulation layer 300. The encapsulation layer 300 may include at least one organic encapsulation layer and at least one inorganic encapsulation layer. According to some embodiments, FIG. 5 shows that the encapsulation layer 300 includes the first and second inorganic encapsulation layers 310 and 330 and the organic encapsulation layer 320 arranged therebetween.

The first inorganic encapsulation layer 310 and the second inorganic encapsulation layer 330 may include at least one inorganic material among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may each be a single layer or a multilayer, each including the above-described material. The organic encapsulation layer 320 may include a polymer-based material. The polymer-based material may include acrylic resin, epoxy-based resin, polyimide, and polyethylene. According to some embodiments, the organic encapsulation layer 320 may include acrylate.

The touch sensor layer 400 may be arranged on the encapsulation layer 300. The touch sensor layer 400 may include a first touch insulating layer 410, a first touch conductive layer 401, a second touch insulating layer 420, a second touch conductive layer 402, and a planarization layer 430. The touch sensor layer 400 may correspond to the touch screen layer TSL described with reference to FIGS. 2A and 2B.

The first touch insulating layer 410 may protect the encapsulation layer 300 and may prevent or reduce cracks from occurring in, for example, at least one of the first inorganic encapsulation layer 310 and/or the second inorganic encapsulation layer 330. The first touch insulating layer 410 may include an inorganic insulating material. The first touch insulating layer 410 may include, for example, aluminum oxide, titanium oxide, tantalum oxide, hafnium oxide, zinc oxide, silicon oxide, silicon nitride, or/and silicon oxynitride. The first touch insulating layer 410 may have a single-layer or multilayer structure including the above-described inorganic insulating material. In some embodiments, the first touch insulating layer 410 may be omitted.

The first touch conductive layer 401 may be arranged on the first touch insulating layer 410. The first touch conductive layer 401 may include a conductive material. The first touch conductive layer 401 may include, for example, at least one of molybdenum (Mo), aluminum (Al), copper (Cu), or titanium (Ti). According to some embodiments, the first touch conductive layer 401 may have a multilayer structure of Ti/Al/Ti.

The second touch insulating layer 420 may be arranged to cover the first touch conductive layer 401. The second touch insulating layer 420 may include an inorganic insulating material and/or an organic insulating material. The inorganic insulating material may include silicon oxide, silicon nitride, and/or silicon oxynitride, and the organic insulating material may include an acrylic or imide-based organic material.

The second touch conductive layer 402 may be arranged on the second touch insulating layer 420. The second touch insulating layer 420 may include a contact hole, and the second touch conductive layer 402 may be electrically connected to the first touch conductive layer 401 via the contact hole. The second touch conductive layer 402 may include a conductive material. The second touch conductive layer 402 may include, for example, at least one of molybdenum (Mo), aluminum (Al), copper (Cu), or titanium (Ti). According to some embodiments, the second touch conductive layer 402 may have a multilayer structure of Ti/Al/Ti.

The planarization layer 430 may be arranged to cover the second touch conductive layer 402. The planarization layer 430 may be have a flat top surface. The planarization layer 430 may include an organic material. According to some embodiments, the planarization layer 430 may include a polymer-based material. The above-described polymer-based material may be transparent. For example, the planarization layer 430 may include silicone-based resin, acrylic resin, epoxy-based resin, polyimide, and polyethylene. In addition, the planarization layer 430 may include an inorganic material.

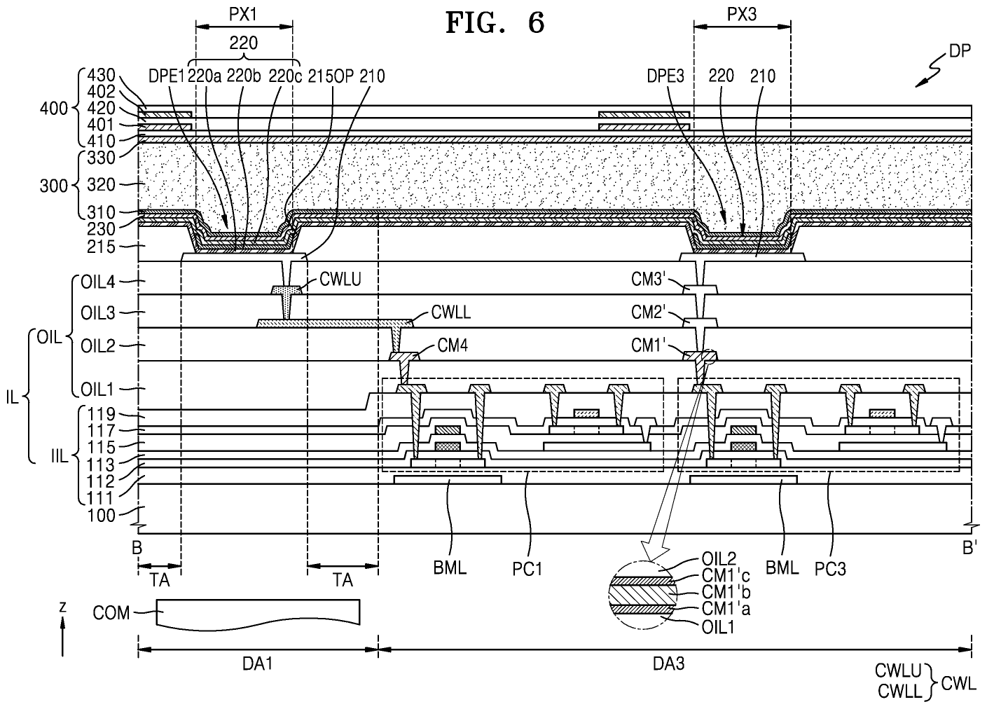

FIG. 6 is a cross-sectional view showing a structure of the display panel DP in the first display region DA1 and the third display region DA3, according to some embodiments, and is a cross-sectional view showing the display panel DP of FIG. 3A taken along a line B-B′ shown in FIG. 3A.

Referring to FIG. 6, the first display element DPE1 corresponding to the first sub-pixel PX1 may be arranged in the first display region DA1. The first display element DPE1 may include the pixel electrode 210 having an edge covered by the bank layer 215, the emission layer 220b overlapping the pixel electrode 210 via the opening 215OP in the bank layer 215, and the opposite electrode 230 on the emission layer 220b. As described above, the first common layer 220a and the second common layer 220c may be arranged between the pixel electrode 210 and the opposite electrode 230.

The first sub-pixel circuit PC1 for driving the first display element DPE1 may be arranged in the third display region DA3. The first sub-pixel circuit PC1 may have the same structure as the second sub-pixel circuit PC2 (FIG. 5) described with reference to FIG. 5. The first display element DPE1 and the first sub-pixel circuit PC1 may not overlap each other.

The first sub-pixel circuit PC1 and the first display element DPE1 may be electrically connected to each other by the connection wire CWL extending from the third display region DA3 toward the first display region DA1. The connection wire CWL may be provided as a plurality. A plurality of connection wires CWL may be electrically connected to a plurality of first sub-pixel circuits PC1, respectively. The plurality of connection wires CWL may electrically connect a plurality of first display elements DPE1 to the plurality of first sub-pixel circuits PC1, respectively. According to some embodiments, the connection wire CWL may include a lower connection wire CWLL and an upper connection wire CWLU.

FIG. 6 shows that the first sub-pixel circuit PC1 and the first display element DPE1 are electrically connected to each other by the lower connection wire CWLL extending from the third display region DA3 toward the first display region DA1. For example, the lower connection wire CWLL may be connected to the first sub-pixel circuit PC1 via a fourth connection electrode CM4, in the third display region DA3. The lower connection wire CWLL may be electrically connected to the pixel electrode 210 of the first display element DPE1 via the upper connection wire CWLU, in the first display region DA1. It is shown that the lower connection wire CWLL is arranged on the second organic insulating layer OIL2 and the upper connection wire CWLU is arranged on the third organic insulating layer OIL3, but according to some embodiments, the lower connection wire CWLL may be arranged under the second organic insulating layer OIL2, for example, on the first organic insulating layer OIL1. In addition, the upper connection wire CWLU may be arranged under the third organic insulating layer OIL3, for example, on the second organic insulating layer OIL2.

The fourth connection electrode CM4 may include a conductive material including molybdenum (Mo), aluminum (Al), copper (Cu), titanium (Ti), etc., and may be formed as a multilayer or a single layer, each including the above material. For example, the fourth connection electrode CM4 may have a multilayer structure of Ti/Al/Ti.

According to some embodiments, at least a portion of the lower connection wire CWLL and/or the upper connection wire CWLU may include a metal or an alloy. For example, at least a portion of the lower connection wire CWLL and/or the upper connection wire CWLU may include at least one of aluminum (Al), copper (Cu), molybdenum (Mo), titanium (Ti), or alloys thereof.

The third display element DPE3 corresponding to the third sub-pixel PX3 may be arranged in the third display region DA3. The third display element DPE3 may include the pixel electrode 210 having an edge covered by the bank layer 215, the emission layer 220b overlapping the pixel electrode 210 via the opening 215OP in the bank layer 215, and the opposite electrode 230 on the emission layer 220b.

The third sub-pixel circuit PC3 for the operation of the third display element DPE3 may be arranged in the third display region DA3 of the substrate 100, and the third sub-pixel circuit PC3 may be electrically connected to the third display element DPE3. The third sub-pixel circuit PC3 may have the same structure as the second sub-pixel circuit PC2 (FIG. 5) described with reference to FIG. 5. The third display element DPE3 may overlap the third sub-pixel circuit PC3.

The third sub-pixel circuit PC3 may be electrically connected to the third display element DPE3 via a fifth connection electrode CM1′, a sixth connection electrode CM2′, and a seventh connection electrode CM3′. The fifth connection electrode CM1′ and the fourth connection electrode CM4 may be arranged on a same layer (for example, the first organic insulating layer OIL1) and may include a same material. The sixth connection electrode CM2′ and the lower connection wire CWLL may be arranged on a same layer (for example, the second organic insulating layer OIL2) and may include a same material. The seventh connection electrode CM3′ and the upper connection wire CWLU may be arranged on a same layer (for example, the third organic insulating layer OIL3) and may include a same material.

The fifth connection electrode CM1′ may include the first connection electrode CM1 (FIG. 5) shown in FIG. 5. For example, the fifth connection electrode CM1′ may include a conductive material including molybdenum (Mo), aluminum (Al), copper (Cu), titanium (Ti), etc., and may be formed as a multilayer or a single layer, each including the above material. According to some embodiments, the fifth connection electrode CM1′ may have a triple-layer structure of Ti/Al/Ti, including a first layer CM1′a, a second layer CM1′b, and a third layer CM1′c.

The encapsulation layer 300 and the touch sensor layer 400 may be arranged on the first display element DPE1 and the third display element DPE3, and their structures are the same as previously described with reference to FIG. 5.

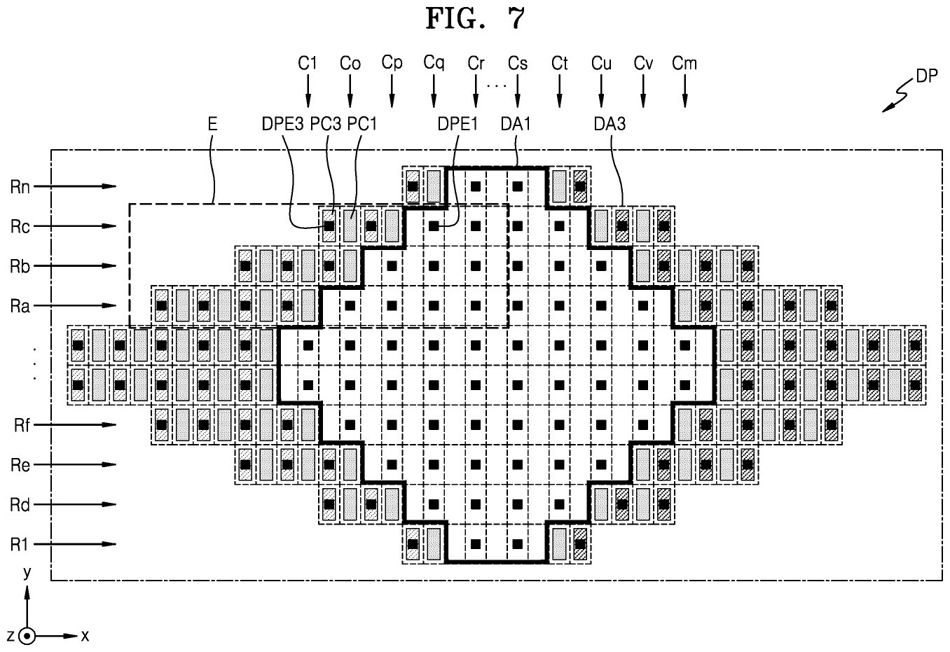

FIG. 7 is a plan view schematically showing the first display region DA1 and the third display region DA3 of the display panel DP according to some embodiments.

Referring to FIG. 7, the first display elements DPE1 are arranged in the first direction (for example, x direction or row direction) and the second direction (for example, y direction or column direction), in the first display region DA1. For example, the first display elements DPE1 may be arranged along a first row R1 to an n^{th} row Rn and a first column C1 to an mth column Cm (wherein each of n and m is a natural number of 3 or more). The first sub-pixel circuits PC1 may not be arranged in the first display region DA1. For example, the first sub-pixel circuits PC1 may not overlap the first display region DA1.

FIG. 7 shows that the first display region DA1 has a step-shaped outline, but embodiments according to the present disclosure are not limited thereto, and the first display region DA1 may have a circular (or substantially circular shape).

According to some embodiments, a row closer to the center of the first display region DA1 may have a relatively large width in the first direction (for example, x direction or row direction). In other words, the width of the first display region DA1 in the first direction (for example, x direction or row direction) in a row relatively closer to the center of the first display region DA1 may be larger than the width of the first display region DA1 in the first direction (for example, x direction or row direction) in a row relatively farther from the center of the first display region DA1.

For example, the width of the first display region DA1 in the first direction (for example, x direction or row direction) in an a^{th} row Ra may be larger than the width of the first display region DA1 in the first direction (for example, x direction or row direction) in a b^{th} row Rb. For example, the width of the first display region DA1 in the first direction (for example, x direction or row direction) in the b^{th} row Rb may be larger than the width of the first display region DA1 in the first direction (for example, x direction or row direction) in a c^{th} row Rc. At this time, a, b, and c are different natural numbers, wherein b is greater than a, and c is greater than b. For example, the first display region DA1 may include a region of which the width in the first direction decreases in the second direction.

For example, the width of the first display region DA1 in the first direction (for example, x direction or row direction) in a d^{th} row Rd may be smaller than the width of the first display region DA1 in the first direction (for example, x direction or row direction) in an eth row Re. For example, the width of the first display region DA1 in the first direction (for example, x direction or row direction) in the eth row Re may be smaller than the width of the first display region DA1 in the first direction (for example, x direction or row direction) in an f^{th} row Rf. At this time, d, e, and f are different natural numbers, wherein e is greater than d, and f is greater than e. For example, the first display region DA1 may include a region of which the width in the first direction increases in the second direction.

According to some embodiments, the number of first display elements DPE1 arranged in a row closer to the center of the first display region DA1 may be greater than the number of first display elements DPE1 arranged in a row relatively farther from the center of the first display region DA1.

For example, the number of first display elements DPE1 arranged in the a^{th} row Ra of the first display region DA1 may be greater than the number of first display elements DPE1 arranged in the b^{th} row Rb of the first display region DA1. For example, the number of first display elements DPE1 arranged in the b^{th} row Rb of the first display region DA1 may be greater than the number of first display elements DPE1 arranged in the c^{th} row Rc of the first display region DA1. At this time, a, b, and c are different natural numbers, wherein b is greater than a, and c is greater than b.

For example, the number of first display elements DPE1 arranged in the d^{th} row Rd of the first display region DA1 may be smaller than the number of first display elements DPE1 arranged in the eth row Re of the first display region DA1. For example, the number of first display elements DPE1 arranged in the eth row Re of the first display region DA1 may be smaller than the number of first display elements DPE1 arranged in the f^{th} row Rf of the first display region DA1. At this time, d, e, and f are different natural numbers, wherein e is greater than d, and f is greater than e.

According to some embodiments, a column closer to the center of the first display region DA1 may have a relatively large width in the second direction (for example, y direction or column direction). In other words, the width of the first display region DA1 in the second direction (for example, y direction or column direction) in a column relatively closer to the center of the first display region DA1 may be larger than the width of the first display region DA1 in the second direction (for example, y direction or column direction) in a column relatively farther from the center of the first display region DA1.

For example, the width of the first display region DA1 in the second direction (for example, y direction or column direction) in a o^{th} column Co may be smaller than the width of the first display region DA1 in the second direction (for example, y direction or column direction) in a p^{th} column Cp. For example, the width of the first display region DA1 in the second direction (for example, y direction or column direction) in a p^{th} column Cp may be smaller than the width of the first display region DA1 in the second direction (for example, y direction or column direction) in a q^{th} column Cq. For example, the width of the first display region DA1 in the second direction (for example, y direction or column direction) in the q^{th} column Cq may be smaller than the width of the first display region DA1 in the second direction (for example, y direction or column direction) in an r^{th} column Cr. At this time, o, p, q, and r are different natural numbers, wherein p is greater than o, q is greater than p, and r is greater than q. For example, the first display region DA1 may include a region of which the width in the second direction increases in the first direction.

For example, the width of the first display region DA1 in the second direction (for example, y direction or column direction) in an s^{th} column Cs may be greater than the width of the first display region DA1 in the second direction (for example, y direction or column direction) in a t^{th} column Ct. For example, the width of the first display region DA1 in the second direction (for example, y direction or column direction) in the t^{th} column Ct may be greater than the width of the first display region DA1 in the second direction (for example, y direction or column direction) in an u^{th} column Cu. For example, the width of the first display region DA1 in the second direction (for example, y direction or column direction) in the u^{th} column Cu may be greater than the width of the first display region DA1 in the second direction (for example, y direction or column direction) in an vth column Cv. At this time, s, t, u, and v are different natural numbers, wherein t is greater than s, u, and v is greater than t, and v is greater than u. For example, the first display region DA1 may include a region of which the width in the second direction decreases in the first direction.

According to some embodiments, the number of first display elements DPE1 arranged in a column closer to the center of the first display region DA1 may be greater than the number of first display elements DPE1 arranged in a column relatively farther from the center of the first display region DA1.

For example, the number of first display elements DPE1 arranged in the p^{th} column Cp of the first display region DA1 may be smaller than the number of first display elements DPE1 arranged in the q^{th} column Cq of the first display region DA1. For example, the number of first display elements DPE1 arranged in the q^{th} column Cq of the first display region DA1 may be smaller than the number of first display elements DPE1 arranged in the r^{th} column Cr of the first display region DA1. At this time, p, q, and r are different natural numbers, wherein q is greater than p, and r is greater than q.

For example, the number of first display elements DPE1 arranged in the s^{th} column Cs of the first display region DA1 may be greater than the number of first display elements DPE1 arranged in the t^{th} column Ct of the first display region DA1. For example, the number of first display elements DPE1 arranged in the t^{th} column Ct of the first display region DA1 may be greater than the number of first display elements DPE1 arranged in the u^{th} column Cu of the first display region DA1. At this time, s, t, and u are different natural numbers, wherein t is greater than s, and u is greater than t.

According to some embodiments, the third display region DA3 may be arranged at opposite sides of the first display region DA1.

According to some embodiments, third display elements DPE3, third sub-pixel circuits PC3 electrically connected to the third display elements DPE3, respectively, and the first sub-pixel circuits PC1 may be arranged in a plurality of rows of the third display region DA3 corresponding to rows in which the first display elements DPE1 are arranged. The third display elements DPE3 and the third sub-pixel circuits PC3 may respectively overlap each other, and the third sub-pixel circuits PC3 and the first sub-pixel circuits PC1 may be arranged alternately.

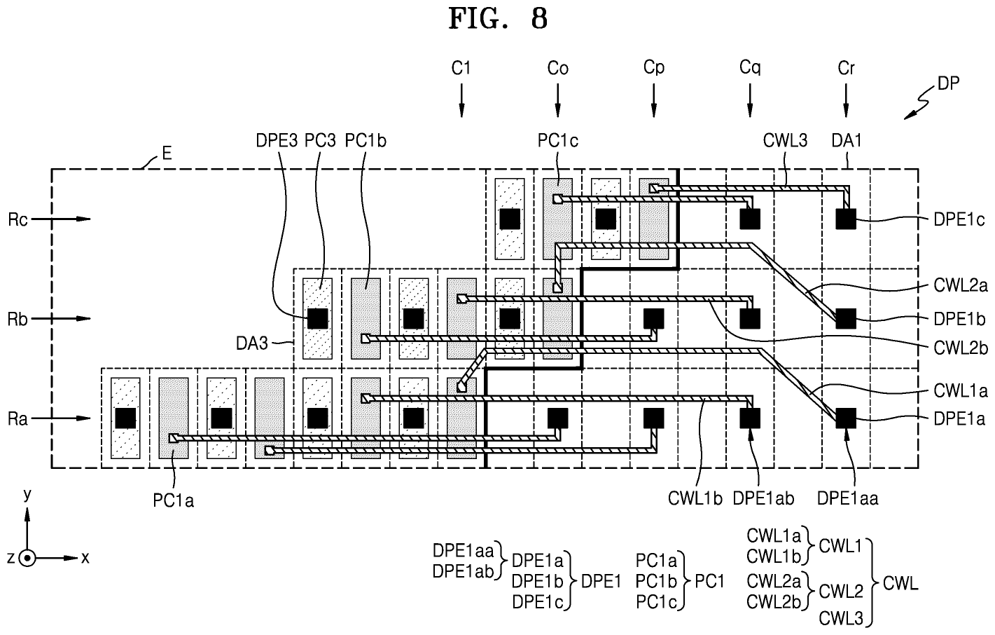

FIG. 8 is a plan view showing a portion of each of the first display region DA1 and the third display region DA3 of the display panel DP according to some embodiments, and is an enlarged view schematically showing an enlarged region ‘E’ of FIG. 7.

Referring to FIG. 8, the first display elements DPE1 arranged in the first display region DA1 may be respectively connected to the first sub-pixel circuits PC1 arranged in the third display region DA3 by the connection wires CWL.

The plurality of first display elements DPE1 may include first-1 display elements DPE1a arranged in the a^{th} row Ra, first-2 display elements DPE1b arranged in the b^{th} row Rb, and first-3 display elements DPE1c arranged in the c^{th} row Rc. The number of first-1 display elements DPE1a arranged in the a^{th} row Ra may be greater than the number of first-2 display elements DPE1b arranged in the b^{th} row Rb. The number of first-2 display elements DPE1b arranged in the b^{th} row Rb may be greater than the number of first-3 display elements DPE1c arranged in the c^{th} row Rc.

The plurality of first sub-pixel circuits PC1 may include first-1 sub-pixel circuits PC1a electrically connected to the first-1 display elements DPE1a, respectively, first-2 sub-pixel circuits PC1b electrically connected to the first-2 display elements DPE1b, respectively, and first-3 sub-pixel circuits PC1c electrically connected to the first-3 display elements DPE1c, respectively.

The first-1 sub-pixel circuits PC1a may be arranged in a row corresponding to a row in which the first-1 display elements DPE1a are arranged. In other words, the first-1 sub-pixel circuits PC1a may be arranged in the a^{th} row Ra. The first-2 sub-pixel circuits PC1b may be arranged in a row corresponding to a row in which the first-2 display elements DPE1b are arranged. In other words, the first-2 sub-pixel circuits PC1b may be arranged in the b^{th} row Rb. The first-3 sub-pixel circuits PC1c may be arranged in a row corresponding to a row in which the first-3 display elements DPE1c are arranged. In other words, the first-3 sub-pixel circuits PC1c may be arranged in the c^{th} row Rc.

According to some embodiments, each of the plurality of connection wires CWL may include a metal or an alloy. For example, both a portion of each of the plurality of connection wires CWL, which is arranged in the first display region DA1, and a portion of each of the plurality of connection wires CWL, which is arranged in the third display region DA3, may include a metal or an alloy. For example, each of the plurality of connection wires CWL may include at least one of aluminum (Al), copper (Cu), molybdenum (Mo), titanium (Ti), or alloys thereof. According to some embodiments, the plurality of connection wires CWL may be a single layer or a multilayer. For example, as shown in FIG. 6, the plurality of connection wires CWL may have a multilayer structure including the lower connection wire CWLL (FIG. 6) and the upper connection wire CWLU (FIG. 6) on the lower connection wire CWLL, and each of the lower connection wire CWLL (FIG. 6) and the upper connection wire CWLU (FIG. 6) may include a metal or an alloy.

In a comparative example, when the plurality of connection wires CWL include only a transparent conductive material, the transparent conductive material has a higher resistance than a metal or an alloy, and the widths of connection wires increase, and thus, the number of connection wires that may be arranged per unit area may be reduced. Therefore, in the case of the comparative example, the number of display elements that may be arranged per unit area in the first display region DA1 may be reduced.

In contrast, according to some embodiments, at least a portion of each connection wire CWL includes a metal or an alloy and thus has a relatively low resistance, and thus, the number of connection wires CWL that may be arranged per unit area may be increased. Because the number of connection wires CWL that may be arranged per unit area increases, the number of display elements that may be arranged per unit area in the first display region DA1 increases, and thus, the resolution of the first display region DA1 may be increased. Because each connection wire CWL has a low resistance, the arrangement of the connection wires CWL and the first sub-pixel circuits PC1 may be changed in various ways. For example, because each connection wire CWL may extend relatively further from the first display region DA1, the arrangement of the first sub-pixel circuits PC1 may be efficiently changed.

The plurality of connection wires CWL may include first connection wires CWL1 respectively connecting the first-1 sub-pixel circuits PC1a to the first-1 display elements DPE1a, second connection wires CWL2 respectively connecting the first-2 sub-pixel circuits PC1b to the first-2 display elements DPE1b, and third connection wires CWL3 respectively connecting the first-3 sub-pixel circuits PC1c to the first-3 display elements DPE1c.

According to some embodiments, one of connection wire among the connection wires CWL arranged in each row may include a portion extending along a row different from a row in which the first display element DPE1 to which the one connection wire is connected is arranged. For example, one of connection wire among the connection wires CWL may include a portion extending along another row in which a relatively smaller number of first display elements DPE1 are arranged than a row in which the first display element DPE1 to which the connection wire is connected is arranged of which the width in the first direction. In other words, one of connection wire among the connection wires CWL may include a portion extending along a row of which the width in the first direction is relatively smaller than a row in which the first display element DPE1 to which the connection wire is connected is arranged. In this case, overcrowding of the connection wires CWL may be prevented or reduced in a row in which a relatively large number of first display elements DPE1 are arranged. For example, the arrangement of the connection wires CWL may be distributed. Accordingly, the transmittance of the first display region DA1 may be increased.

According to some embodiments, one of the first connection wires CWL1 connected to the first-1 display elements DPE1a arranged in the a^{th} row Ra may include a portion extending along the b^{th} row Rb. For example, the first connection wire CWL1 may include a first-1 connection wire CWL1a including a portion extending along the b^{th} row Rb. For example, a portion of the first-1 connection wire CWL1a may overlap the first-2 sub-pixel circuit PC1b.

According to some embodiments, a first-1 display element DPE1aa connected to the first-1 connection wire CWL1a may be arranged closer to the center of the first display region DA1 than a first-1 display element DPE1ab connected to a first-2 connection wire CWL1b may be. For example, the first-1 display element DPE1aa connected to the first-1 connection wire CWL1a may be arranged in an r^{th} column Cr, and the first-1 display element DPE1ab connected to the first-2 connection wire CWL1b may be arranged in a q^{th} column Cq.

According to some embodiments, another one of the first connection wires CWL1 connected to the first-1 display elements DPE1a arranged in the a^{th} row Ra may extend along the a^{th} row Ra. For example, the first connection wire CWL1 may include the first-2 connection wire CWL1b extending along only the a^{th} row Ra. For example, the first-2 connection wire CWL1b may not overlap the first-2 sub-pixel circuit PC1b. In other words, in a plan view, the first-2 connection wire CWL1b may be spaced apart from the first-2 sub-pixel circuit PC1b.

According to some embodiments, one of the second connection wires CWL2 connected to the first-2 display elements DPE1b arranged in the b^{th} row Rb may include a portion extending along the c^{th} row Rc. For example, the second connection wire CWL2 may include a second-1 connection wire CWL2a including a portion extending along the c^{th} row Rc. For example, a portion of the second-1 connection wire CWL2a may overlap the first-3 sub-pixel circuit PC1c.

According to some embodiments, another one of the second connection wires CWL2 connected to the first-2 display elements DPE1b arranged in the b^{th} row Rb may extend along the b^{th} row Rb. For example, the second connection wire CWL2 may include a second-2 connection wire CWL2b extending along only the b^{th} row Rb. For example, the second-2 connection wire CWL2b may not overlap the first-3 sub-pixel circuit PC1c. In other words, in a plan view, the second-2 connection wire CWL2b may be spaced apart from the first-3 sub-pixel circuit PC1c.

FIG. 8 shows that each of the third connection wires CWL3 extends along only the c^{th} row Rc, but embodiments according to the present disclosure are not limited thereto. For example, one of the third connection wires CWL3 may include a portion extending to pass through another row, similar to the first-1 connection wire CWL1a and the second-1 connection wire CWL2a.

FIG. 8 shows that the a^{th} row Ra, the b^{th} row Rb, and the c^{th} row Rc are adjacent to each other, but embodiments according to the present disclosure are not limited thereto. For example, at least one row may be arranged between the a^{th} row Ra and the b^{th} row Rb, and at least one row may be arranged between the b^{th} row Rb and the c^{th} row Rc.

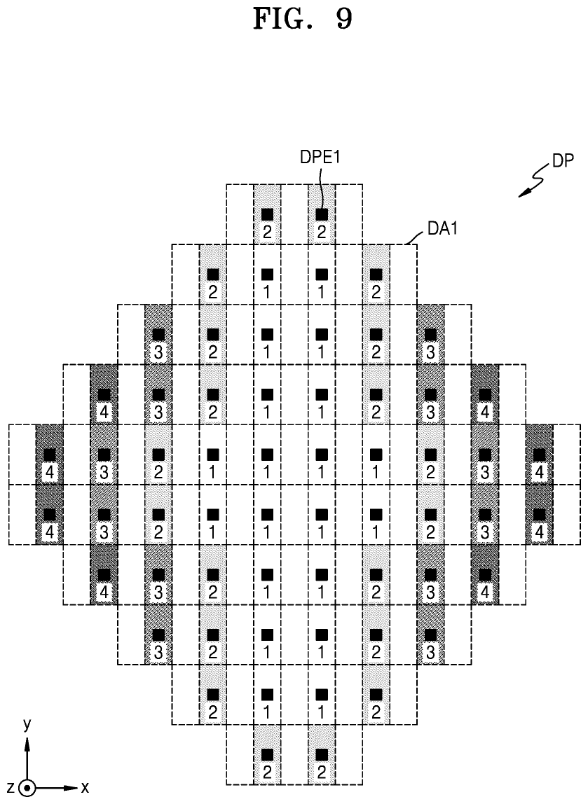

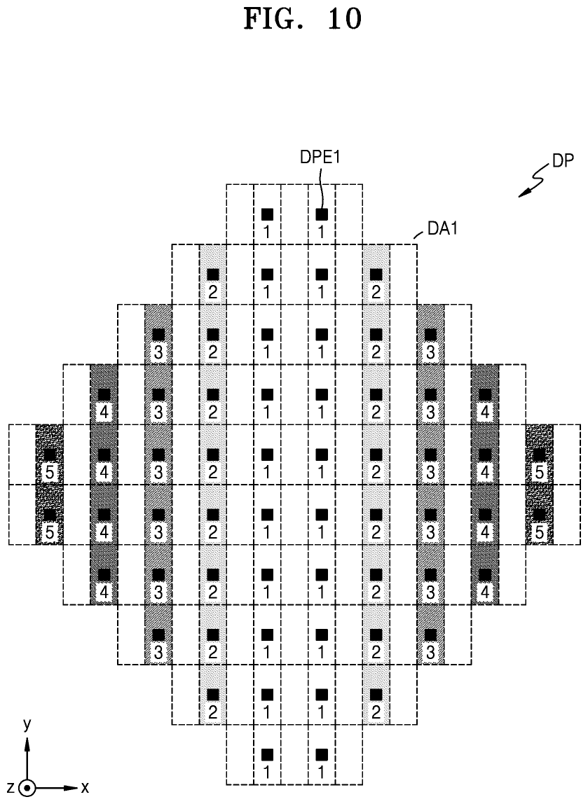

FIG. 9 is a plan view showing the density of connection wires in the first display region DA1 of the display panel DP according to some embodiments. FIG. 10 is a plan view showing the density of connection wires in a first display region DA1 of a display panel according to a comparative example.

FIG. 9 shows the density of connection wires when a connection wire CWL arranged in a row includes a portion extending along another row, in which a relatively smaller number of first display elements DPE1 are arranged, as described with reference to FIG. 8. In contrast, FIG. 10 shows the density of connection wires when each of the connection wires extends only along the row in which the first display element connected to the connection wire is arranged. For example, FIG. 10 shows a case where a first connection wire connected to first display elements arranged in an a^{th} row does not include a portion passing through another row and is arranged along only the a^{th} row. 1, 2, 3, 4, and 5 shown in each of FIGS. 9 and 10 each indicate the number of connection wires passing through each region.

In the comparative example of FIG. 10, as a distance from the center of the first display region DA1 increases in the +x direction and −x direction, the density of connection wires gradually increases, and the density of connection wires in a row in which a largest number of first display elements are arranged increases significantly. In this case, the transmittance is significantly reduced in an edge region of the first display region DA1, resulting in deterioration in the sensing recognition rate of a component.

Referring to FIG. 9, according to some embodiments, the arrangement of the connection wires CWL may be distributed from rows with a large number of first display elements DPE1 (FIG. 7) to a row with a relatively small number of first display elements DPE1 (FIG. 7). According to some embodiments, the density of connection wires gradually increases in a similar shape to that of the first display region DA1, and thus, connection wires may be distributed as much as possible to avoid overcrowding. Accordingly, the transmittance may be increased by relatively reducing the density of connection wires in the first display region DA1, compared to the comparative example of FIG. 10. The transmittance in the first display region DA1 increases, and thus, the sensing recognition rate of the component COM (FIG. 2A) may be increased.

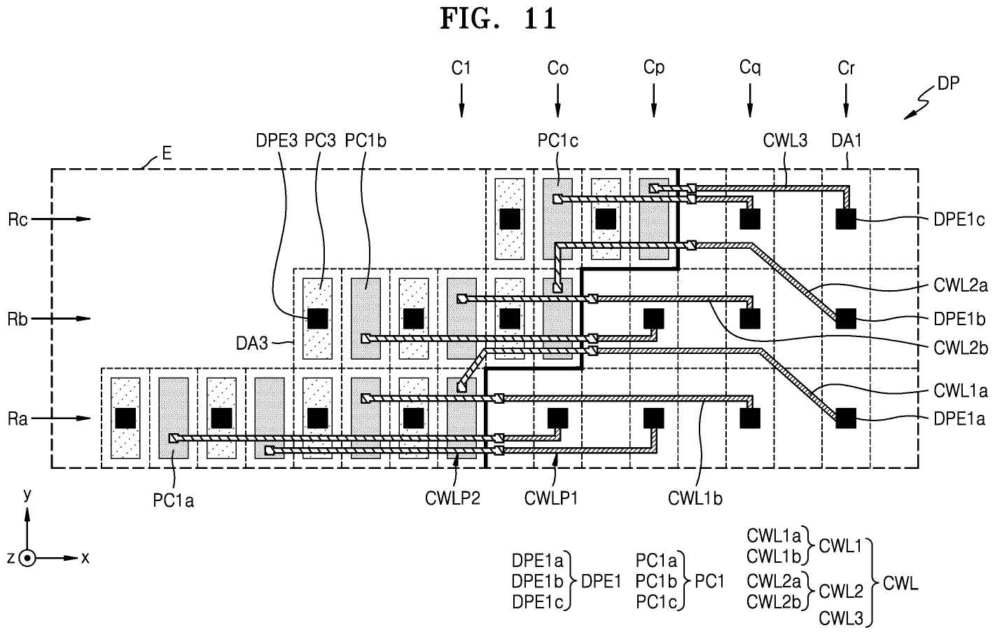

FIG. 11 is a plan view showing a portion of each of the first display region DA1 and the third display region DA3 of the display panel DP according to some embodiments, and is an enlarged view schematically showing an enlarged region ‘E’ of FIG. 7.

Referring to FIG. 11, each of the plurality of connection wires CWL may include a first portion CWLP1 arranged in the first display region DA1 and a second portion CWLP2 arranged in the third display region DA3. According to some embodiments, the first portion CWLP1 and the second portion CWLP2 of each of the plurality of connection wires CWL may be arranged on different layers from each other and may be electrically connected to each other by a contact hole or a connection structure.

According to some embodiments, the first portion CWLP1 and the second portion CWLP2 of each of the plurality of connection wires CWL may include different materials. For example, the first portion CWLP1 of each of the connection wires CWL may include a transparent conductive material, and the second portion CWLP2 may include a metal or an alloy. For example, the first portion CWLP1 of each of the connection wires CWL may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). For example, the second portion CWLP2 of each of the connection wires CWL may include at least one of aluminum (Al), copper (Cu), molybdenum (Mo), titanium (Ti), or alloys thereof.

According to some embodiments, because the first portion CWLP1 of each of the plurality of connection wires CWL, which is arranged in the first display region DA1, includes a transparent conductive material, the transmittance of the display panel DP in the first display region DA1 may be increased. In addition, because the second portion CWLP2 of each of the plurality of connection wires CWL, which is arranged in the third display region DA3, includes a metal or an alloy, the arrangement of the connection wires CWL and the first sub-pixel circuits PC1 may be changed in various ways. For example, the number of connection wires CWL that may be arranged per unit area in the third display region DA3 may be increased, and because each connection wire CWL may extend relatively further from the first display region DA1, the arrangement of the first sub-pixel circuits PC1 may be efficiently changed. In other words, the plurality of connection wires CWL according to some embodiments may increase the transmittance in the first display region DA1 and simultaneously increase the degree of freedom in designing the arrangement of the connection wires CWL and the first sub-pixel circuits PC1.

According to some embodiments, as described with reference to FIG. 8, one of connection wire (for example, the first-1 connection wire CWL1a or the second-1 connection wire CWL2a) among the connection wires CWL arranged in each row may include a portion extending along a row different from a row in which the first display element DPE1 to which the one of connection wire is connected is arranged. Therefore, according to some embodiments, even when the first portion CWLP1 of each of the connection wires CWL includes a transparent conductive material, compared to the comparative example in which the connection wires CWL are extend to pass through only a single row and include a transparent conductive material, the number of first display elements DPE1 per unit area arranged in one row may be increased. Accordingly, according to some embodiments, the resolution of the first display region DA1 may be increased compared to the comparative example.

According to some embodiments, the plurality of connection wires CWL may be a single layer or a multilayer. For example, the first portion CWLP1 of the connection wire CWL may correspond to the upper connection wire CWLU (FIG. 6), and the second portion CWLP2 of the connection wire CWL may correspond to the lower connection wire CWLL (FIG. 6). For example, the upper connection wire CWLU (FIG. 6) may overlap the first display region DA1 and include a transparent conductive material, and at least a portion of the lower connection wire CWLL (FIG. 6) may overlap the third display region DA3 and include a metal or an alloy.

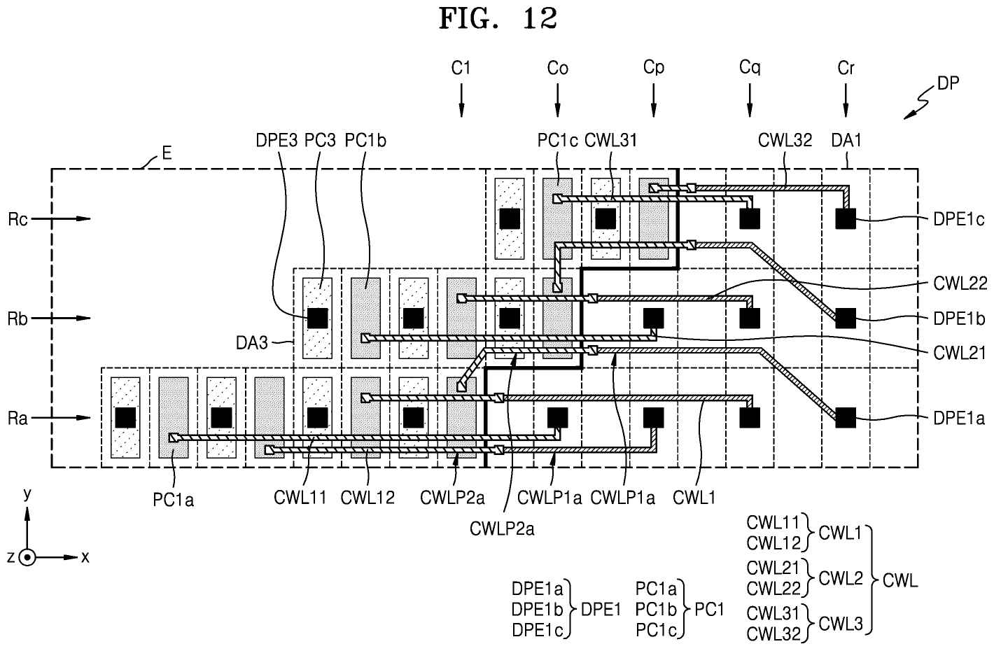

FIG. 12 is a plan view showing a portion of each of the first display region DA1 and the third display region DA3 of the display panel DP according to some embodiments, and is an enlarged view schematically showing an enlarged region ‘E’ of FIG. 7.

Referring to FIG. 12, one of the plurality of connection wires CWL may include a metal or an alloy, and at least a portion of another one may include a transparent conductive material. According to some embodiments, one of the plurality of connection wires CWL arranged in one row may include a metal or an alloy, and at least a portion of another one may include a transparent conductive material.

For example, a first-3 connection wire CWL11 among the first connection wires CWL1 arranged in the a^{th} row Ra may include a metal or an alloy and may not include a transparent conductive material. For example, a portion of the first-3 connection wire CWL11, which is arranged in the first display region DA1, and a portion of the first-3 connection wire CWL11, which is arranged in the third display region DA3, may each include a metal or an alloy. For example, a first-4 connection wire CWL12 among the first connection wires CWL1 arranged in the a^{th} row Ra may include a first portion CWLP1a arranged in the first display region DA1 and including a transparent conductive material and a second portion CWLP2a arranged in the third display region DA3 and including a metal or an alloy.

For example, a second-3 connection wire CWL21 among the second connection wires CWL2 arranged in the b^{th} row Rb may include a metal or an alloy and may not include a transparent conductive material. For example, a portion of the second-3 connection wire CWL21, which is arranged in the first display region DA1, and a portion of the second-3 connection wire CWL21, which is arranged in the third display region DA3, may each include a metal or an alloy. For example, a second-4 connection wire CWL22 among the second connection wires CWL2 arranged in the b^{th} row Rb may include the first portion CWLP1a arranged in the first display region DA1 and including a transparent conductive material and the second portion CWLP2a arranged in the third display region DA3 and including a metal or an alloy.

For example, a third-3 connection wire CWL31 among the third connection wires CWL3 arranged in the c^{th} row Rc may include a metal or an alloy and may not include a transparent conductive material. For example, a portion of the third-3 connection wire CWL31, which is arranged in the first display region DA1, and a portion of the third-3 connection wire CWL31, which is arranged in the third display region DA3, may each include a metal or an alloy. For example, a third-4 connection wire CWL32 among the third connection wires CWL3 arranged in the c^{th} row Rc may include the first portion CWLP1a arranged in the first display region DA1 and including a transparent conductive material and the second portion CWLP2a arranged in the third display region DA3 and including a metal or an alloy.

FIG. 12 shows that each of connection wires respectively corresponding to the first-1 connection wire CWL1a, and the second-1 connection wire CWL2a described with reference to FIG. 8 includes the first portion CWLP1a and the second portion CWLP2a, but embodiments according to the present disclosure are not limited thereto. According to some embodiments, a connection wire corresponding to the first-1 connection wire CWL1a (FIG. 8) may include a metal or an alloy and may not include a transparent conductive material.

The plurality of connection wires CWL of FIG. 12 according to some embodiments include a connection wire, which at least partially includes a transparent conductive material, and a connection wire, which includes a metal or an alloy, in a region overlapping the first display region DA1, and thus, the transmittance may be relatively improved and the degree of freedom in designing the connection wire CWL may be increased at the same time.

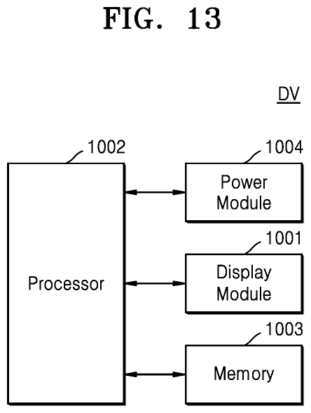

FIG. 13 is a block diagram of the electronic device DV according to an embodiment.

Referring to FIG. 13, the electronic device DV according to an embodiment may include a display module 1001, a processor 1002, a memory 1003, and a power module 1004.

The display module 1001 may include the display panel DP described above.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic device DV.

At least one of the components of the electronic device DV described above may be included in a display apparatus. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus DV except for the display apparatus.

In an embodiment, the display module 1001 included in the display apparatus may drive based on the image data signal and the input control signal received from the processor 1002.

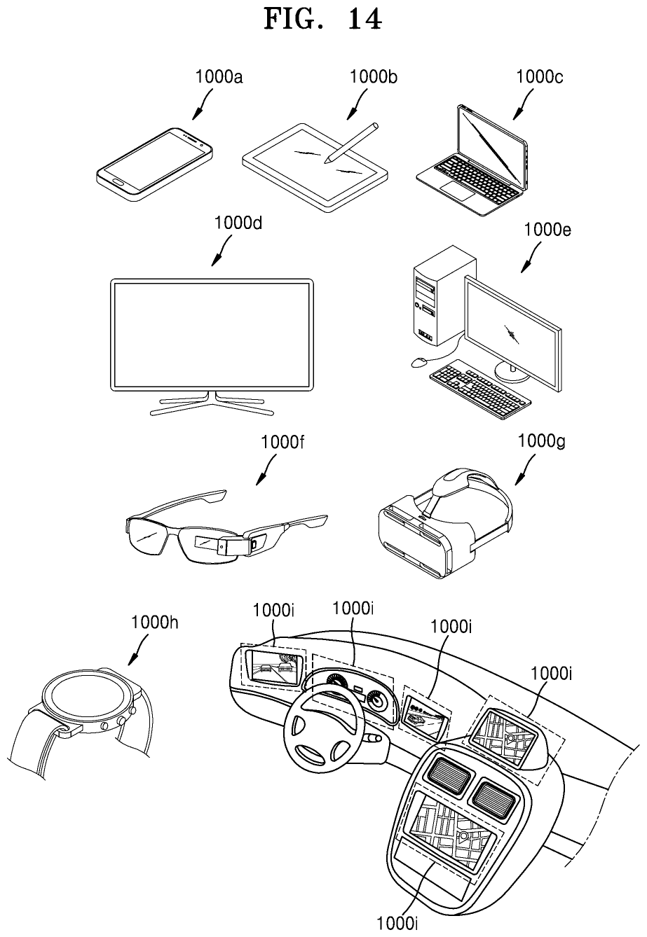

FIG. 14 is schematic diagrams of electronic devices according to various embodiments.

Referring to FIG. 14, various electronic devices to which display panels according to embodiments are applied may include not only image display electronic devices such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) disposed in the dashboard and a room mirror display.

As described above, according to some embodiments, a display panel with relatively improved reliability and relatively improved visibility and an electronic device including the same may be implemented. However, the scope of embodiments according to the present disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
a substrate comprising a first display region, a second display region surrounding at least a portion of the first display region, and a third display region between the first display region and the second display region;
a plurality of first display elements arranged along a plurality of rows and a plurality of columns, in the first display region;
a plurality of first sub-pixel circuits in the third display region and electrically connected to the plurality of first display elements, respectively; and
a plurality of connection wires electrically connecting the first display elements to the first sub-pixel circuits, respectively,
wherein the plurality of first display elements comprise first-1 display elements arranged in an a^{th} row and first-2 display elements arranged in a b^{th} row (wherein a and b are different natural numbers),
the plurality of first sub-pixel circuits comprise first-1 sub-pixel circuits in the a^{th} row and electrically connected to the first-1 display elements, respectively,
the plurality of connection wires comprise first connection wires connecting the first-1 display elements to the first-1 sub-pixel circuits, respectively,
a number of the first-1 display elements in the a^{th} row is greater than a number of the first-2 display elements arranged in the b^{th} row, and
one of the first connection wires comprises a portion extending along the b^{th} row.

2. The display panel of claim 1, wherein a width of the first display region in a row direction in the a^{th} row is greater than a width of the first display region in the row direction in the b^{th} row.

3. The display panel of claim 1, wherein at least a portion of each of the plurality of connection wires comprises a metal or an alloy.

4. The display panel of claim 1, wherein at least a portion of each of the plurality of connection wires comprises at least one of aluminum, copper, molybdenum, titanium, or alloys thereof.

5. The display panel of claim 1, wherein a portion of each of the plurality of connection wires comprises a transparent conductive material, and a remaining portion of each of the plurality of connection wires comprises a metal or an alloy.

6. The display panel of claim 5, wherein each of the plurality of connection wires comprises: a first portion in the first display region and comprising a transparent conductive material; and a second portion in the third display region and comprising a metal or an alloy.

7. The display panel of claim 6, wherein the first portion and the second portion of each of the plurality of connection wires are on different layers from each other.

8. The display panel of claim 1, wherein one of the plurality of connection wires comprises a metal or an alloy, and at least a portion of another one of the plurality of connection wires comprises a transparent conductive material.

9. The display panel of claim 8, wherein another one of the plurality of connection wires comprises:
a third portion in the first display region and comprising a transparent conductive material; and
a fourth portion in the third display region and comprising a metal or an alloy.

10. The display panel of claim 1, wherein another one of the first connection wires extends along the a^{th} row.

11. The display panel of claim 1, wherein the plurality of first display elements further comprise first-3 display elements arranged in a c^{th} row (wherein c is a natural number different from a and b),
the plurality of first sub-pixel circuits further comprise first-2 sub-pixel circuits arranged in the b^{th} row and electrically connected to the first-2 display elements, respectively, and first-3 sub-pixel circuits arranged in the c^{th} row and electrically connected to the first-3 display elements, respectively,
the plurality of connection wires further comprise second connection wires connecting the first-2 display elements to the first-2 sub-pixel circuits, respectively,
a number of the first-2 display elements in the b^{th} row is greater than a number of the first-3 display elements in the c^{th} row, and
one of the second connection wires comprises a portion extending along the c^{th} row.

12. The display panel of claim 11, wherein another one of the second connection wires extends along the b^{th} row.

13. The display panel of claim 1, further comprising:
a plurality of second display elements in the second display region;
a plurality of second sub-pixel circuits in the second display region and electrically connected to the plurality of second display elements, respectively;
a plurality of third display elements in the third display region; and
a plurality of third sub-pixel circuits in the third display region and electrically connected to the plurality of third display elements, respectively.

14. A display panel comprising:
a first display region, a second display region surrounding at least a portion of the first display region and having lower transmittance than the first display region, and a third display region between the first display region and the second display region;
a plurality of display elements in the first display region;
a plurality of sub-pixel circuits in the third display region and electrically connected to the plurality of display elements, respectively; and
a plurality of connection wires electrically connecting the display elements to the sub-pixel circuits, respectively,
wherein one connection wire among the connection wires comprises:
a first portion in the first display region and comprising a transparent conductive material; and
a second portion in the third display region and comprising a metal or an alloy.

15. The display panel of claim 14, wherein the plurality of display elements comprise:
a plurality of first display elements arranged in an a^{th} row of the first display region; and
a plurality of second display elements arranged in a b^{th} row of the first display region (wherein a and b are different natural numbers),
wherein a width of the first display region in a row direction in the a^{th} row is greater than a width of the first display region in the row direction in the b^{th} row,
the first display elements comprise a first-1 display element and a first-2 display element,
among the plurality of connection wires, a first connection wire connected to the first-1 display element comprises a portion extending along the b^{th} row, and
among the plurality of connection wires, a second connection wire connected to the first-2 display element extends along the a^{th} row.

16. The display panel of claim 15, wherein the first-1 display element is arranged in an r^{th} column,
the first-2 display element is arranged in a q^{th} column (wherein r and q are different natural numbers), and
a width of the first display region in a column direction in the r^{th} column is greater than a width of the first display region in the column direction in the q^{th} column.

17. The display panel of claim 15, wherein the first-1 display element is closer to a center of the first display region than the first-2 display element.

18. The display panel of claim 14, wherein each of the connection wires comprises the first portion and the second portion.

19. The display panel of claim 14, wherein another one of the connection wires comprises:
a third portion in the first display region; and
a fourth portion in the third display region, wherein each of the third and fourth portions comprises a metal or an alloy.

20. An electronic device comprising:
a display panel comprising a first display region, a second display region surrounding at least a portion of the first display region, and a third display region between the first display region and the second display region; and
a component on a lower surface of the display panel and overlapping at least a portion of the first display region,
wherein the display panel comprises:
a plurality of first display elements arranged along a plurality of rows and a plurality of columns, in the first display region;
a plurality of first sub-pixel circuits in the third display region and electrically connected to the plurality of first display elements, respectively; and
a plurality of connection wires electrically connecting the first display elements to the first sub-pixel circuits, respectively,
the plurality of first display elements comprise first-1 display elements in an a^{th} row and first-2 display elements in a b^{th} row (wherein a and b are different natural numbers),
the plurality of first sub-pixel circuits comprise first-1 sub-pixel circuits in the a^{th} row and electrically connected to the first-1 display elements, respectively,
the plurality of connection wires comprise first connection wires connecting the first-1 display elements to the first-1 sub-pixel circuits, respectively,
a number of the first-1 display elements in the a^{th} row is greater than a number of the first-2 display elements in the b^{th} row, and
one of the first connection wires comprises a portion extending along the b^{th} row.
